(19) United States
(12) Patent Application Publication
(10) Pub. No.: US 2021/0281017 A1
(43) Pub. Date: Sep. 9, 2021

(54) MULTICORE CABLE-WITH-CONNECTOR

(71) Applicant: SUMITOMO ELECTRIC INDUSTRIES, LTD., Osaka (JP)

(72) Inventors: Naoshige YOKOTA, Tochigi (JP); Masaki SUZUKI, Tochigi (JP)

(21) Appl. No.: 17/104,556

(22) Filed: Nov. 25, 2020

(30) Foreign Application Priority Data
Mar. 6, 2020 (JP) 2020-039103

(51) Int. Cl. H01R 13/6466; H05K 1/11; H05K 1/02; H05K 1/18

(52) U.S. Cl. CPC H01R 13/6466; H05K 1/113; H01R 24/60; H05K 1/181; H05K 1/0231; H05K 1/0218

(57) ABSTRACT

A multicore cable-with-connector includes: a connector, which includes a first ground guard between first and second pads and connected to first and second central conductors on a first surface of a substrate and a second ground guard between third and fourth pads connected to third and fourth central conductors on a second surface. When viewed in a first direction, a projected image of the first guard overlaps 50% or more of projected images of first and second layered structures respectively composed of the first pad and portion of the first conductor and the second pad and portion of the second conductor, and a projected image of the second guard overlaps 50% or more of projected images of third and fourth layered structures respectively composed of the third pad and portion of the third central conductor and the fourth pad and portion of the fourth conductor.

### CROSS-REFERENCE TO RELATED APPLICATION

The present application is based upon and claims priority to Japanese Patent Application No. 2020-039103, filed on Mar. 6, 2020, the entire contents of which are incorporated herein by reference.

### BACKGROUND OF THE INVENTION

### 1. Field of the Invention

The present disclosure relates to a multicore cable-with-connector.

### 2. Description of the Related Art

Patent Document 1 discloses, as a multicore cable-with-connector that is used for transmission between electronic devices, a multicore cable-with-connector that can be connected to an electronic device regardless of the vertical orientation of the connector.

### PRIOR ART DOCUMENT

### Patent Document

[Patent Document 1] Japanese Laid-open Patent Publication No. 2017-69152

Although a desired purpose can be achieved by the multicore cable disclosed in Patent Document 1, crosstalk may occur if the frequency of a transmitted signal is high.

The present disclosure has an object to provide a multicore cable-with-connector that enabled to reduce crosstalk.

### SUMMARY OF THE INVENTION

According to the present disclosure, a multicore cable-with-connector includes: a first coaxial wire including a first central conductor; a second coaxial wire including a second central conductor; a third coaxial wire including a third central conductor; a fourth coaxial wire including a fourth central conductor; and a connector connected to one end of the first coaxial wire, one end of the second coaxial wire, one end of the third coaxial wire, and one end of the fourth coaxial wire, wherein the connector includes a substrate having a first surface and a second surface that is an opposite side of the first surface, wherein the substrate includes a first pad provided on the first surface and to which the first central conductor is connected; a second pad provided on the first surface and to which the second central conductor is connected; a third pad provided on the second surface and to which the third central conductor is connected; a fourth pad provided on the second surface and to which the fourth central conductor is connected; and a ground layer provided between the first surface and the second surface, wherein the first pad and the second pad are arranged in a particular first direction, wherein the third pad and the fourth pad are in the first direction, wherein the connector includes a first ground guard provided between the first pad and the second pad on the first surface and connected to the ground layer; and a second ground guard provided between the third pad and the fourth pad on the second surface and connected to the ground layer, wherein when viewed in the first direction, a projected image of the first ground guard overlaps 50% or more of a projected image of a first layered structure composed of the first pad and a portion of the first central conductor overlapping the first pad in a top view of the first surface, the projected image of the first ground guard overlaps 50% or more of a projected image of a second layered structure composed of the second pad and a portion of the second central conductor overlapping the second pad in the top view, a projected image of the second ground guard overlaps 50% or more of a projected image of a third layered structure composed of the third pad and a portion of the third central conductor overlapping the third pad in the top view, and the projected image of the second ground guard overlaps 50% or more of a projected image of a fourth layered structure composed of the fourth pad and a portion of the fourth central conductor overlapping the fourth pad in the top view.

According to the present disclosure, it is possible to reduce crosstalk.

### BRIEF DESCRIPTION OF THE DRAWINGS

FIG. 1 is a perspective view illustrating a configuration of a multicore cable-with-connector according to an embodiment;

FIG. 2 is a top view illustrating an example of pads and connector pads provided on a first substrate;

FIG. 3 is a bottom view illustrating an example of pads and connector pads provided on the first substrate;

FIG. 4 is a top view illustrating the first substrate, coaxial wires, electric wires and capacitors;

FIG. 5 is a bottom view illustrating the first substrate, coaxial wires, electric wires and capacitors;

FIG. 6 is a cross-sectional view illustrating the first substrate, coaxial wires, and capacitors (part 1);

FIG. 7 is a cross-sectional view illustrating the first substrate, coaxial wires, and capacitors (part 2);

FIG. 8 is a cross-sectional view illustrating the first substrate, coaxial wires, and capacitors (part 3);

FIG. 9 is a cross-sectional view illustrating the first substrate, coaxial wires, and capacitors (part 4);

FIG. 10 is a cross-sectional view illustrating the first substrate, coaxial wires, capacitors, and an IC chip;

FIG. 11 is a cross-sectional view illustrating the first substrate, electric wires, capacitors, and the IC chip;

FIG. 12 is a top view illustrating an example of pads and connector pads provided on a second substrate;

FIG. 13 is a bottom view illustrating an example of pads and connector pads provided on the second substrate;

FIG. 14 is a top view illustrating the second substrate, coaxial wires, electric wires and capacitors;

FIG. 15 is a bottom view illustrating the second substrate, coaxial wires, electric wires, and capacitors;

FIG. 16 is a cross-sectional view illustrating the second substrate, coaxial wires, electric wires, and capacitors (part 1);

FIG. 17 is a bottom view illustrating a modified example of ground guards on the second surface of the second substrate; and

FIG. 18 is a schematic view illustrating the modified example of the ground guards on the second surface of the second substrate.

### DESCRIPTION OF THE PREFERRED EMBODIMENTS

In the following, an embodiment will be described.

[Description of Embodiment of The Present Disclosure]

<1> According to one aspect of the present disclosure, a multicore cable-with-connector includes: a first coaxial wire including a first central conductor; a second coaxial wire including a second central conductor; a third coaxial wire including a third central conductor; a fourth coaxial wire including a fourth central conductor; and a connector connected to one end of the first coaxial wire, one end of the second coaxial wire, one end of the third coaxial wire, and one end of the fourth coaxial wire, wherein the connector includes a substrate having a first surface and a second surface that is an opposite side of the first surface, wherein the substrate includes a first pad provided on the first surface and to which the first central conductor is connected; a second pad provided on the first surface and to which the second central conductor is connected; a third pad provided on the second surface and to which the third central conductor is connected; a fourth pad provided on the second surface and to which the fourth central conductor is connected; and a ground layer provided between the first surface and the second surface, wherein the first pad and the second pad are arranged in a particular first direction, wherein the third pad and the fourth pad are in the first direction, wherein the connector includes a first ground guard provided between the first pad and the second pad on the first surface and connected to the ground layer; and a second ground guard provided between the third pad and the fourth pad on the second surface and connected to the ground layer, wherein when viewed in the first direction, a projected image of the first ground guard overlaps 50% or more of a projected image of a first layered structure composed of the first pad and a portion of the first central conductor overlapping the first pad in a top view of the first surface, the projected image of the first ground guard overlaps 50% or more of a projected image of a second layered structure composed of the second pad and a portion of the second central conductor overlapping the second pad in the top view, a projected image of the second ground guard overlaps 50% or more of a projected image of a third layered structure composed of the third pad and a portion of the third central conductor overlapping the third pad in the top view, and the projected image of the second ground guard overlaps 50% or more of a projected image of a fourth layered structure composed of the fourth pad and a portion of the fourth central conductor overlapping the fourth pad in the top view.

The first central conductor and the second central conductor are connected to the first pad and the second pad, respectively, and the third central conductor and the fourth central conductor are connected to the third pad and the fourth pad, respectively. The first ground guard is provided between the first pad and the second pad, and the second ground guard is provided between the third pad and the fourth pad. The first ground guard and the second ground guard are connected to the ground layer. When viewed in the first direction, the projected image of the first ground guard overlaps 50% or more of the projected image of the first layered structure and overlaps 50% or more of the projected image of the second layered structure, and the projected image of the second ground guard overlaps 50% or more of the projected image of the third layered structure and overlaps 50% or more of the projected image of the fourth layered structure. Therefore, even in a case in which the frequency of a signal that is transmitted through the first coaxial wire, the second coaxial wire, the third coaxial wire, and the fourth coaxial wire is high, for example, even in a case in which the frequency is about 20 GHz, crosstalk between the first coaxial wire and the second coaxial wire and crosstalk between the third coaxial wire and the fourth coaxial wire can be suppressed.

<2> In the multicore cable-with-connector according to <1>, wherein when viewed in the first direction, a position of the first ground guard in a direction parallel to the first surface may overlap 50% or more of a position of the first pad in the direction parallel to the first surface, the position of the first ground guard in the direction parallel to the first surface may overlap 50% or more of a position of the second pad in the direction parallel to the first surface, a position of the second ground guard in the direction parallel to the first surface may overlap 50% or more of a position of the third pad in the direction parallel to the first surface, and the position of the second ground guard in the direction parallel to the first surface may overlap 50% or more of a position of the fourth pad in the direction parallel to the first surface. Crosstalk is easily suppressed.

<3> In the multicore cable-with-connector according to <1> or <2>, wherein a first maximum height of the first ground guard from the first surface may be greater than or equal to a first distance between a first top portion of the first central conductor on the first pad and the first surface, wherein the first maximum height may be greater than or equal to than a second distance between a second top portion of the second central conductor on the second pad and the first surface, wherein a second maximum height of the second ground guard from the second surface may be greater than or equal to a third distance between a third top portion of the third central conductor on the third pad and the second surface, and wherein the second maximum height may be greater than or equal to a fourth distance between a fourth top portion of the fourth central conductor on the fourth pad and the second surface. Crosstalk is easily suppressed.

<4> In the multicore cable-with-connector according to <3>, wherein the first coaxial wire may include a first insulating layer provided on a periphery of the first central conductor; a first outer conductor provided on a periphery of the first insulating layer; and a first insulating jacket provided on a periphery of the first outer conductor, wherein the second coaxial wire may include a second insulating layer provided on a periphery of the second central conductor; a second outer conductor provided on a periphery of the second insulating layer; and a second insulating jacket provided on a periphery of the second outer conductor, wherein the third coaxial wire may include a third insulating layer provided on a periphery of the third central conductor; a third outer conductor provided on a periphery of the third insulating layer; and a third insulating jacket provided on a periphery of the third outer conductor, wherein the fourth coaxial wire may include a fourth insulating layer provided on a periphery of the fourth central conductor; a fourth outer conductor provided on a periphery of the fourth insulating layer; and a fourth insulating jacket provided on a periphery of the fourth outer conductor, wherein the substrate may include a first ground pad provided on the first surface and to which the first outer conductor is connected; a second ground pad provided on the first surface and to which the second outer conductor is connected; a third ground pad provided on the second surface and to which the third outer conductor is connected; and a fourth ground pad provided on the second surface and to which the fourth outer conductor is connected; wherein the first maximum height may be greater than or equal to a fifth distance between a fifth top portion of the first central conductor on the first ground pad and the first surface, wherein the first maximum height may be greater than or equal to a sixth distance between a sixth top portion of the second central conductor on the second ground pad and the first surface, wherein the second maximum height may be greater than or equal to a seventh distance between a seventh top portion of the third central conductor on the third ground pad and the second surface, and wherein the second maximum height may be greater than or equal to an eighth distance between an eighth top portion of the fourth central conductor on the fourth ground pad and the second surface. Crosstalk is easily suppressed.

<5> In the multicore cable-with-connector according to any one of <1>to <4>, wherein in a second direction perpendicular to the first surface, the first pad may face the third pad, wherein in the second direction perpendicular to the first surface, the second pad may face the fourth pad, wherein in the second direction perpendicular to the first surface, the ground layer may include a first ground portion between the first pad and the third pad; and a second ground portion between the second pad and the fourth pad. Crosstalk between the first coaxial wire and the third coaxial wire and crosstalk between the second coaxial wire and the fourth coaxial wire can be suppressed.

<6> The multicore cable-with-connector according to any one of <1> to <5>further may include: a fifth coaxial wire including a fifth central conductor; a sixth coaxial wire including a sixth central conductor; a seventh coaxial wire including a seventh central conductor; and an eighth coaxial wire including an eighth central conductor, wherein one end of the fifth coaxial wire, one end of the sixth coaxial wire, one end of the seventh coaxial wire, and one end of the eighth coaxial wire may be connected to the connector, wherein the substrate may include a fifth pad provided on the first surface and to which the fifth central conductor is connected; a sixth pad provided on the first surface and to which the sixth central conductor is connected; a seventh pad provided on the second surface and to which the seventh central conductor is connected; and an eighth pad provided on the second surface and to which the eighth central conductor is connected, wherein a first differential signal may be transmitted to the first coaxial wire and the fifth coaxial wire, wherein a second differential signal may be transmitted to the second coaxial wire and the sixth coaxial wire, wherein a third differential signal may be transmitted to the third coaxial wire and the seventh coaxial wire, wherein a fourth differential signal may be transmitted to the fourth coaxial wire and the eighth coaxial wire, wherein in the first direction, the first pad may be provided between the first ground guard and the fifth pad, wherein in the first direction, the second pad may be provided between the first ground guard and the sixth pad, wherein in the first direction, the third pad may be provided between the second ground guard and the seventh pad, and wherein in the first direction, the fourth pad may be provided between the second ground guard and the eighth pad. Crosstalk when a differential signal is transmitted can be suppressed.

<7> in the multicore cable-with-connector according to any one of <1> to <6>, a ninth distance between the first pad and the second pad in the first direction may be greater than or equal to 30% of a tenth distance between two points where a straight line extending in the first direction and passing through the first pad and the second pad intersects edges of the substrate, and an eleventh distance between the third pad and the fourth pad in the first direction may be greater than or equal to 30% of a twelfth distance between two points where a straight line extending in the first direction and passing through the third pad and the fourth pad intersects edges of the substrate. This is for easily ensuring areas for the first ground guard and the second ground guard.

<8> In the multicore cable-with-connector according to any one of <1> to <7>, the first ground guard and the second ground guard may each include a capacitor or an integrated circuit chip. The first ground guard and the second ground guard can be configured by the capacitor or the integrated circuit chip provided on the connector.

<9> In the multicore cable-with-connector according to any one of <1> to <8>, wherein a plurality of first ground guards may be provided between the first pad and the second pad on the first surface, and wherein when viewed in the first direction, a first combined projected image obtained by superimposing projected images of the plurality of first ground guards may overlap 50% or more of the projected image of the first layered structure and may overlap 50% or more of the projected image of the second layered structure. Even when the individual first ground guards are small, crosstalk can be suppressed by the plurality of first ground guards.

<10> In the multicore cable-with-connector according to any one of <1> to <9>, wherein a plurality of second ground guards may be provided between the third pad and the fourth pad on the second surface, and wherein when viewed in the first direction, a second combined projected image obtained by superimposing projected images of the plurality of second ground guards may overlap 50% or more of the projected image of the third layered structure and may overlap 50% or more of the projected image of the fourth layered structure. Even when the individual second ground guards are small, crosstalk can be suppressed by the plurality of second ground guards.

<11> According to another aspect of the present disclosure, a multicore cable-with-connector includes: a first coaxial wire; a second coaxial wire; a third coaxial wire; a fourth coaxial wire; a fifth coaxial wire; a sixth coaxial wire; a seventh coaxial wire; an eighth coaxial wire; and a connector connected to one end of the first coaxial wire, one end of the second coaxial wire, one end of the third coaxial wire, one end of the fourth coaxial wire, one end of the fifth coaxial wire, one end of the sixth coaxial wire, one end of the seventh coaxial wire, and one end of the eighth coaxial wire, wherein the first coaxial wire includes a first central conductor; a first insulating layer provided on a periphery of the first central conductor; a first outer conductor provided on a periphery of the first insulating layer; and a first insulating jacket provided on a periphery of the first outer conductor, wherein the second coaxial wire includes a second central conductor; a second insulating layer provided on a periphery of the second central conductor; a second outer conductor provided on a periphery of the second insulating layer; and a second insulating jacket provided on a periphery of the second outer conductor, wherein the third coaxial wire includes a third central conductor; a third insulating layer provided on a periphery of the third central conductor; a third outer conductor provided on a periphery of the third insulating layer; and a third insulating jacket provided on a periphery of the third outer conductor, wherein the fourth coaxial wire includes a fourth central conductor; a fourth insulating layer provided on a periphery of the fourth central conductor; a fourth outer conductor provided on a periphery of the fourth insulating layer; and a fourth insulating jacket provided on a periphery of the fourth outer conductor, wherein the fifth coaxial wire includes a fifth central conductor; a fifth insulating layer provided on a periphery of the fifth central conductor; a fifth outer conductor provided on a periphery of the fifth insulating layer; and a fifth insulating jacket provided on a periphery of the fifth outer conductor, wherein the sixth coaxial wire includes a sixth central conductor; a sixth insulating layer provided on a periphery of the sixth central conductor; a sixth outer conductor provided on a periphery of the sixth insulating layer; and a sixth insulating jacket provided on a periphery of the sixth outer conductor, wherein the seventh coaxial wire includes a seventh central conductor; a seventh insulating layer provided on a periphery of the seventh central conductor; a seventh outer conductor provided on a periphery of the seventh insulating layer; and a seventh insulating jacket provided on a periphery of the seventh outer conductor, wherein the eighth coaxial wire includes an eighth central conductor; an eighth insulating layer provided on a periphery of the eighth central conductor; an eighth outer conductor provided on a periphery of the eighth insulating layer; and an eighth insulating jacket provided on a periphery of the eighth outer conductor, wherein a first differential signal is transmitted to the first coaxial wire and the fifth coaxial wire, wherein a second differential signal is transmitted to the second coaxial wire and the sixth coaxial wire, wherein a third differential signal is transmitted to the third coaxial wire and the seventh coaxial wire, wherein a fourth differential signal is transmitted to the fourth coaxial wire and the eighth coaxial wire, wherein the connector includes a substrate having a first surface, a second surface that is an opposite side of the first surface, and a third surface that is a surface at a front end in a connector insertion direction and that connects the first surface and the second surface, wherein the substrate includes a first pad provided on the first surface and to which the first central conductor is connected; a second pad provided on the first surface and to which the second central conductor is connected; a third pad provided on the second surface and to which the third central conductor is connected; a fourth pad provided on the second surface and to which the fourth central conductor is connected; a fifth pad provided on the first surface and to which the fifth central conductor is connected; a sixth pad provided on the first surface and to which the sixth central conductor is connected; a seventh pad provided on the second surface and to which the seventh central conductor is connected; an eighth pad provided on the second surface and to which the eighth central conductor is connected; a first ground pad provided on the first surface and to which the first outer conductor and the fifth outer conductor are connected; a second ground pad provided on the first surface and to which the second outer conductor and the sixth outer conductor are connected; a third ground pad provided on the second surface and to which the third outer conductor and the seventh outer conductor are connected; a fourth ground pad provided on the second surface and to which the fourth outer conductor and the eighth outer conductor are connected; and a ground layer provided between the first surface and the second surface, wherein in a top view of the first surface, the first pad and the second pad are arranged in a first direction parallel to the third surface, wherein the third pad and the fourth pad are arranged in the first direction, wherein in a second direction perpendicular to the first surface, the first pad faces the third pad, wherein in the second direction perpendicular to the first surface, the second pad faces the fourth pad, wherein the connector includes a first ground guard including a capacitor that is provided between the first pad and the second pad on the first surface and that is connected to the ground layer; and a second ground guard including a capacitor that is provided between the third pad and the fourth pad on the second surface and that is connected to the ground layer, wherein in the first direction, the first pad is provided between the first ground guard and the fifth pad, wherein in the first direction, the second pad is provided between the first ground guard and the sixth pad, wherein in the first direction, the third pad is provided between the second ground guard and the seventh pad, wherein in the first direction, the fourth pad is provided between the second ground guard and the eighth pad, wherein when viewed in the first direction, a projected image of the first ground guard overlaps 50% or more of a projected image of a first layered structure composed of the first pad and a portion of the first central conductor overlapping the first pad in the top view of the first surface, the projected image of the first ground guard overlaps 50% or more of a projected image of a second layered structure composed of the second pad and a portion of the second central conductor overlapping the second pad in the top view, a projected image of the second ground guard overlaps 50% or more of a projected image of a third layered structure composed of the third pad and a portion of the third central conductor overlapping the third pad in the top view, and the projected image of the second ground guard overlaps 50% or more of a projected image of a fourth layered structure composed of the fourth pad and a portion of the fourth central conductor overlapping the fourth pad in the top view, wherein in the second direction perpendicular to the first surface, the ground layer includes a first ground portion between the first pad and the third pad; and a second ground portion between the second pad and the fourth pad.

Even in a case in which the frequency of first to fourth differential signals that are transmitted through the first to eighth coaxial wires is high, for example, even in a case in which the frequency is about 20 GHz, crosstalk between the first coaxial wire and the second coaxial wire and crosstalk between the third coaxial wire and the fourth coaxial wire can be suppressed.

[Details of Embodiment of The Present Disclosure]

In the following, an embodiment of the present disclosure will be described in detail. However, the present disclosure is not limited to the following embodiment. It should be noted that in the specification and the drawings of the present application, the same reference numerals may be assigned to components having substantially the same function/configuration so that repetitive descriptions may be omitted.

<Configuration of Multicore Cable>

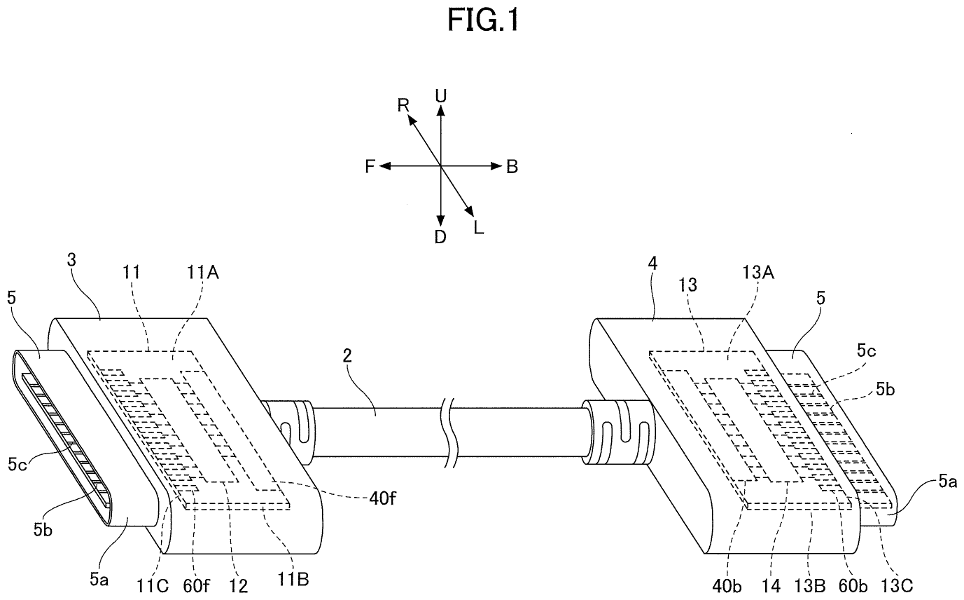

First, a configuration of a multicore cable-with-connector according to the embodiment is described. FIG. 1 is a perspective view illustrating a configuration of a multicore cable-with-connector 1 according to the embodiment.

The multicore cable-with-connector 1 according to the present embodiment may be used, for example, as a cable that connects electronic devices (not illustrated) to each other. It should be noted that in the diagrams such as FIG. 1, U, D, F, B, R, and L indicate directions in the multicore cable-with-connector 1, and U indicates “upward” (or upper), D indicates “downward” (or lower), F indicates “front”, B indicates “back” (or behind), R indicates “right”, and L indicates “left”. The RL direction is an example of a first direction, and the UD direction is an example of a second direction.

As illustrated in FIG. 1, the multicore cable-with-connector 1 includes a multicore cable 2, a first connector 3, and a second connector 4. The first connector 3 is attached to the end portion of the front side (F side) of the multicore cable 2. The second connector 4 is attached to the end portion of the back side (B side) of the multicore cable 2.

The multicore cable-with-connector 1 includes, on the front F of the first connector 3 and the back B of the second connector 4, connector plugs 5 that are to be connected to receptacles (not illustrated) of electronic devices. For each connector plug 5, a metal shell 5a has a substantially oval cylinder shape is provided as a housing. A pin holding plate 5b is housed inside the metal shell 5a. The pin holding plate 5b is a member that holds contact pins 5c to be connected to the receptacle (not shown) of an electronic device. The contact pins 5c are arranged on the pin holding plate 5b such that the contact pins 5c are connectable to the receptacle of an electronic device even if the right-left orientation or the upward-downward orientation of the first connector 3 or the second connector 4 is reversed.

The first connector 3 includes an internal first substrate 11 to which the multicore cable 2 is connected. The first substrate 11 has a first surface 11A, a second surface 11B, and a third surface 11C. In this example, the first surface 11A is the upper surface (U side surface) of the first substrate 11, the second surface 11B is the lower surface (D side surface) of the first substrate 11, and the third surface 11C is the front surface (F side surface) of the first substrate 11. The first substrate 11 includes a first circuit 12, pads 40f connected to the end portion of the back side (B side) of the first circuit 12, and connector pads 60f connected to the end portion of the front side (F side) of the first circuit 12. The pads 40f and the connector pads 60f are provided on the first surface 11A and the second surface 11B of the first substrate 11. For example, the thickness of the first substrate 11 is between 0.5 mm and 1.0 mm. The first substrate 11 is formed in a substantially flat plate shape. Capacitors and a semiconductor integrated circuit (IC) chip are mounted on the first substrate 11.

The second connector 4 includes an internal second substrate 13 to which the multicore cable 2 is connected. The second substrate 13 has a first surface 13A, a second surface 13B, and a third surface 13C. In this example, the first surface 13A is the upper surface (U side surface) of the second substrate 13, the second surface 13B is the lower surface (D side surface) of the second substrate 13, and the third surface 13C is the back surface (B side surface) of the second substrate 13. The second substrate 13 includes a second circuit 14, pads 40b connected to the end portion of the front side (F side) of the second circuit 14, and connector pads 60b connected to the end portion of the back side (B side) of the second circuit 14. The pads 40b and the connector pads 60b are provided on the first surface 13A and the second surface 13B of the second substrate 13. For example, the thickness of the second substrate 13 is between 0.5 mm and 1.0 mm. The second substrate 13 is formed in a substantially flat plate shape. Capacitors are mounted on the second substrate 13.

The multicore cable 2 includes a plurality of pairs of coaxial wires that are high speed signal lines and a plurality of electric wires. For example, each coaxial wire pair is composed of a pair of two wires to transmit a high speed differential signal. Coaxial wires constituting coaxial wire pairs include a central conductor, an insulating layer, an outer conductor, and a jacket in order from the center to the outside. Electric wires are composed of insulated electric wires including a central conductor and a jacket.

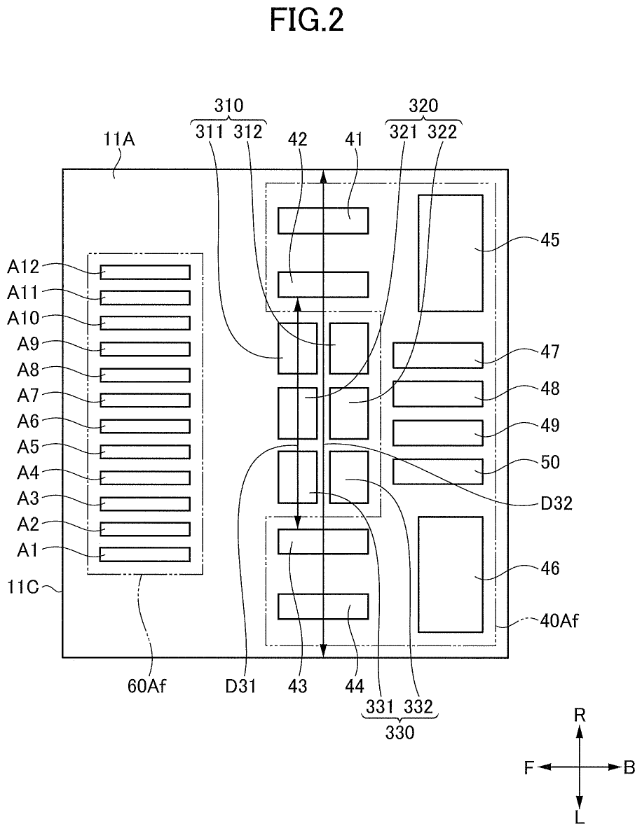

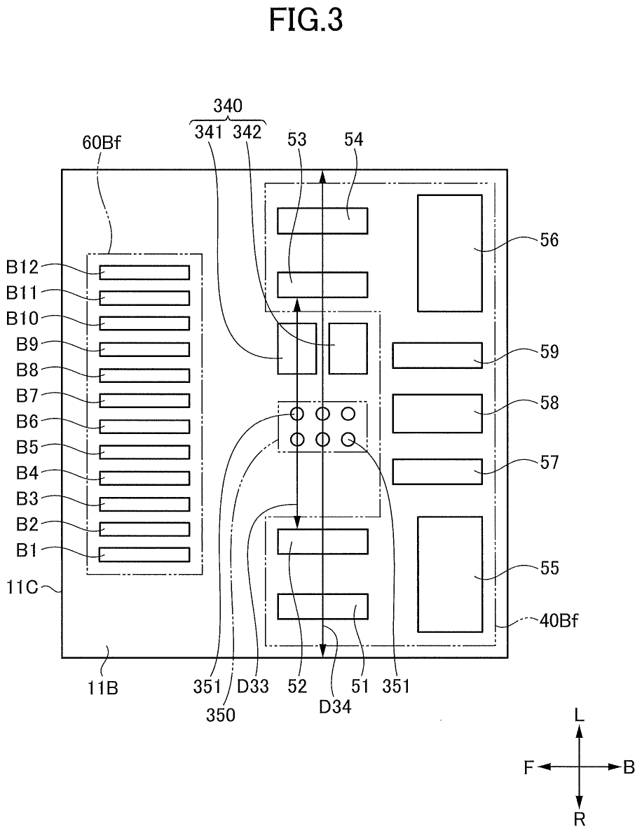

Next, pads included in the pads 40f of the first substrate 11 and connector pads included in the connector pads 60f will be described. FIG. 2 is a top view illustrating an example of pads and connector pads provided on the first substrate 11. FIG. 3 is a bottom view illustrating an example of pads and connector pads provided on the first substrate 11.

The pads 40f include first surface side pads 40Af provided on the first surface 11A and second surface side pads 40Bf provided on the second surface 11B. As illustrated in FIG. 2, the first surface side pads 40Af include pads 41, 42, 43, 44, 45, 46, 47, 48, 49, and 50. As illustrated in FIG. 3, the second surface side pads 40Bf include pads 51, 52, 53, 54, 55, 56, 57, 58, and 59.

As illustrated in FIG. 2, on the first surface 11A, the pad 46 is provided on the left L of the pad 45, and between the pad 45 and the pad 46, the pads 47, 48, 49, and 50 are sequentially provided from the right R to the left L. On the first surface 11A, the pads 41 and 42 are provided on the front F of the pad 45, and the pads 43 and 44 are provided on the front F of the pad 46. The pad 42 is provided on the left L of the pad 41 and the pad 44 is provided on the left L of the pad 43. The pad 43 is provided on the left L of the pad 42. That is, the pad 42 and the pad 43 are arranged in the RL direction parallel to the third surface 11C in the top view of the first surface 11A. Pad pairs 310, 320, and 330 for capacitors are provided between the pad 42 and the pad 43, from right R to left L in order. The pad pair 310 includes a pad 311 and a pad 312, and the pad 311 is provided on the front F of the pad 312. The pad pair 320 includes a pad 321 and a pad 322, and the pad 321 is provided on the front F of the pad 322. The pad pair 330 includes a pad 331 and a pad 332, and the pad 331 is provided on the front F of the pad 332.

As illustrated in FIG. 3, on the second surface 11B, a pad 56 is provided on the left L of the pad 55. Also, between the pad 55 and the pad 56, pads 57, 58 and 59 are provided in order from the right R to the left L. On the second surface 11B, pads 51 and 52 are provided on the front F of the pad 55 and pads 53 and 54 are provided on the front F of the pad 56. The pad 52 is provided on the left L of the pad 51 and the pad 54 is provided on the left L of the pad 53. The pad 53 is provided on the left L of the pad 52. That is, the pad 52 and the pad 53 are arranged in the RL direction parallel to the third surface 11C in the top view of the second surface 11B. A pad pair 340 for a capacitor is provided between the pad 52 and the pad 53. The pad pair 340 includes a pad 341 and a pad 342, and the pad 341 is provided on the front F of the pad 342. Pads 350 for an integrated circuit (IC) chip are provided between the pad pair 340 and the pad 52. The pads 350 include a plurality of pads 351.

The first surface side pads 40Af and the second surface side pads 40Bf are connected to the end portion of the front side (F side) of the multicore cable 2.

The pad 42 is an example of a first pad, the pad 43 is an example of a second pad, the pad 52 is an example of a third pad, and the pad 53 is an example of a fourth pad. The pad 41 is an example of a fifth pad, the pad 44 is an example of a sixth pad, the pad 51 is an example of a seventh pad, and the pad 54 is an example of an eighth pad. The pad 45 is an example of a first ground pad, the pad 46 is an example of a second ground pad, the pad 55 is an example of a third ground pad, and the pad 56 is an example of a fourth ground pad.

The connector pads 60f include first surface side connector pads 60Af provided on the first surface 11A and second surface side connector pads 60Bf provided on the second surface 11B. As illustrated in FIG. 2, the first surface side connector pads 60Af include connector pads A1, A2, A3, A4, A5, A6, A7, A8, A9, A10, A11, and A12. The connector pads A1 to A12 of the first surface side connector pads 60Af are arranged in a row from the left L to the right R in order on the first surface 11A. As illustrated in FIG. 3, the second surface side connector pads 60Bf include connector pads B1, B2, B3, B4, B5, B6, B7, B8, B9, B10, B11, and B12. The connector pads B1 to B12 of the second surface side connector pads 60Bf are arranged in a row from the right R to the left L in order on the second surface 11B.

On the first surface 11A, the connector pads A1 and A12 are ground terminals (GND) for grounding. The connector pads A2 and A3 are terminals (TX1+, TX1−) for high-speed signal transmission. The connector pads A4 and A9 are terminals (VBUS) for bus power supply. The connector pad A5 is a Configuration Channel (CC) terminal. The connector pads A6 and A7 are terminals (D+, D−) for data signals. The connector pad A8 is a terminal (SBU1) for side band. The connector pads A10 and A11 are terminals (RX2+, RX2−) for high-speed signal reception.

On the second surface 11B, the connector pads B1 and B12 are ground terminals (GND) for grounding. The connector pads B2 and B3 are terminals (TX2+, TX2−) for high-speed signal transmission. The connector pads B4 and B9 are terminals (VBUS) for bus power supply. The connector pad B5 is a terminal (VCONN) for connection power supply. The connector pad B8 is a terminal (SBU2) for side band. The connector pads B10 and B11 are terminals (RX1+, RX1−) for high-speed signal reception.

The first surface side pads 40Af and the second surface side pads 40Bf are connected by the first circuit 12 to the first surface side connector pads 60Af and the second surface side connector pads 60Bf of the first substrate 11. For example, the pads 41 to 44 and 51 to 54 are connected to the connector pads A2, A3, A10, A11, B2, B3, B10, and B11, which are terminals for high-speed signal transmission (TX1+, TX1−) or terminals for high-speed signal reception (RX2+, RX2−). For example, the pad 41 is connected to the connector pad A11, the pad 42 is connected to the connector pad A10, the pad 43 is connected to the connector pad A3, and the pad 44 is connected to the connector pad A2. For example, the pad 51 is connected to the connector pad B2, the pad 52 is connected to the connector pad B3, the pad 53 is connected to the connector pad B10, and the pad 54 is connected to the connector pad B11.

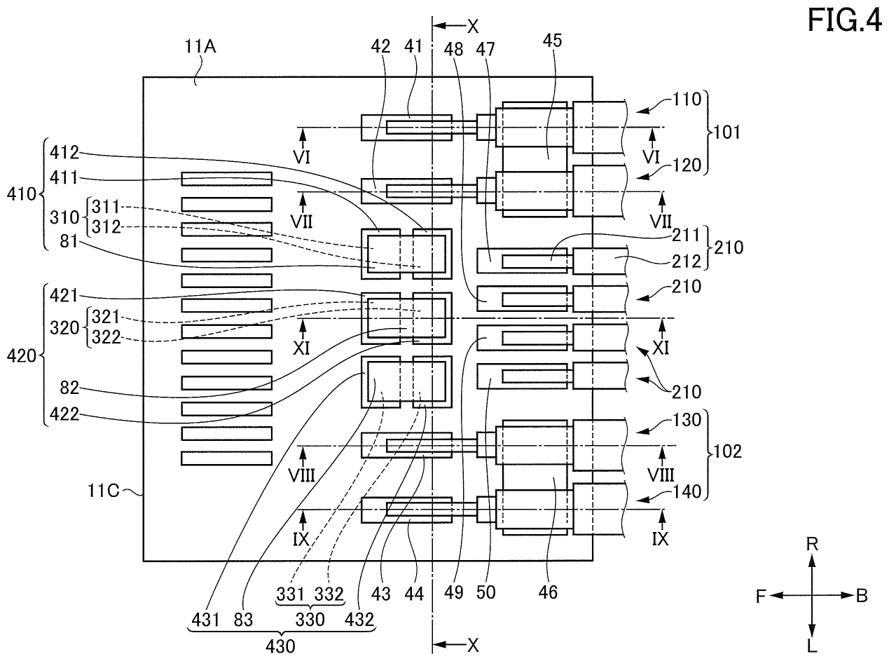

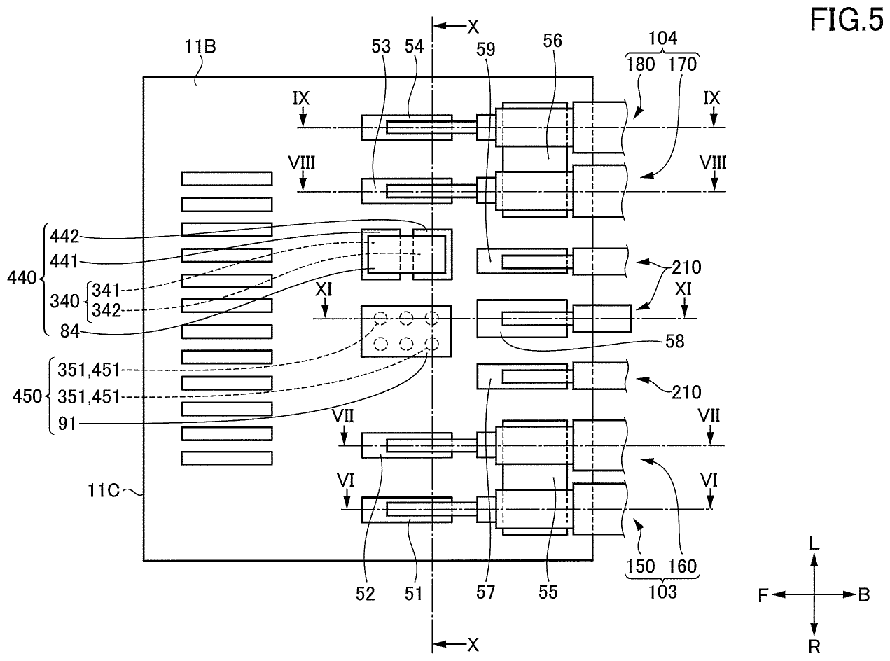

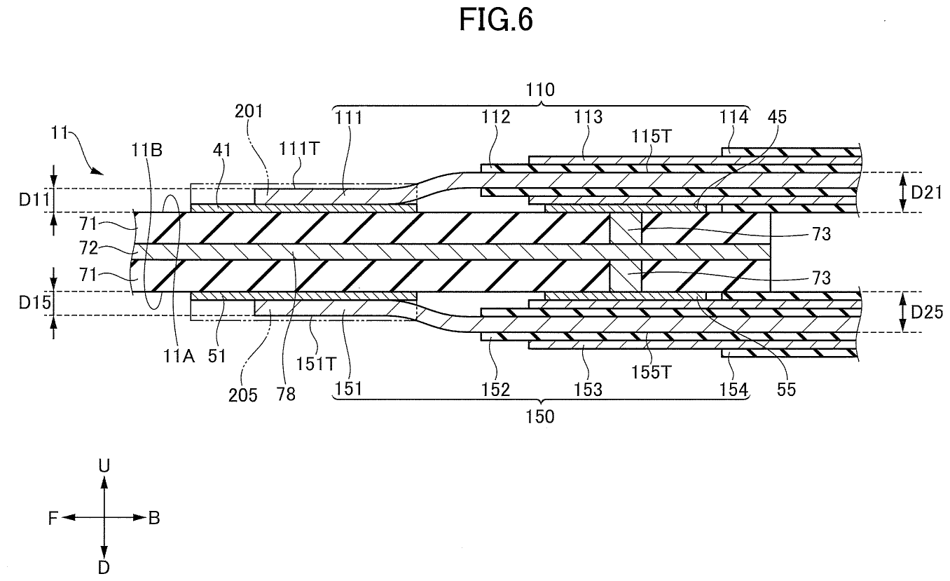

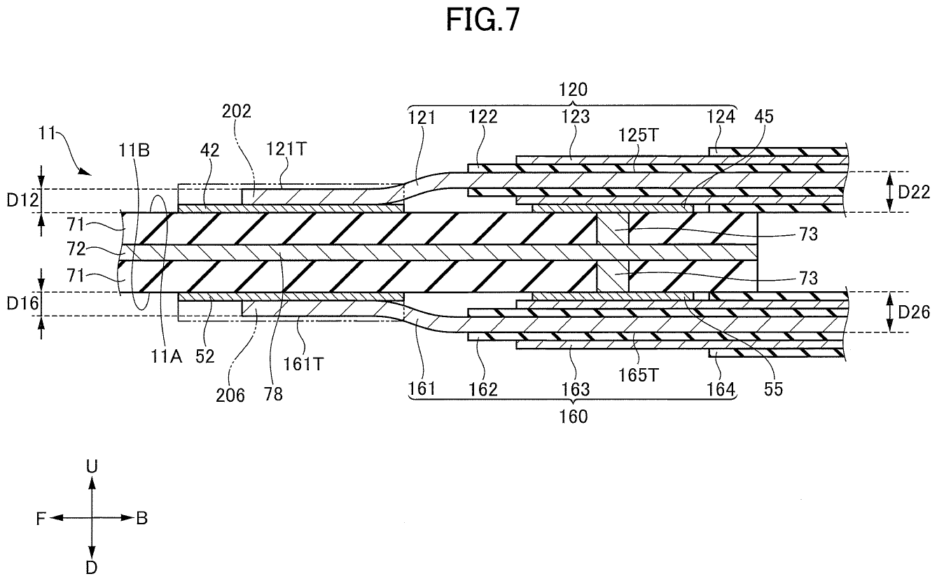

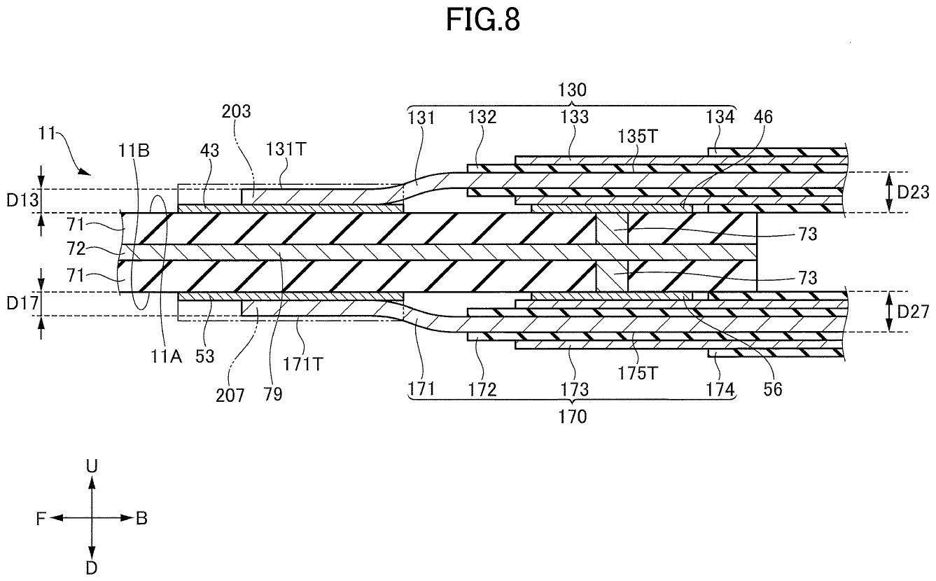

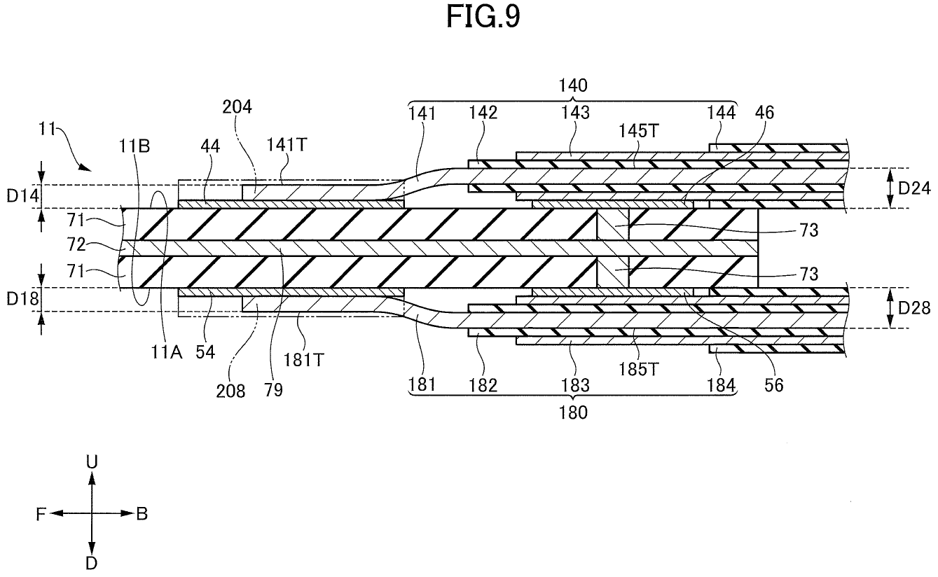

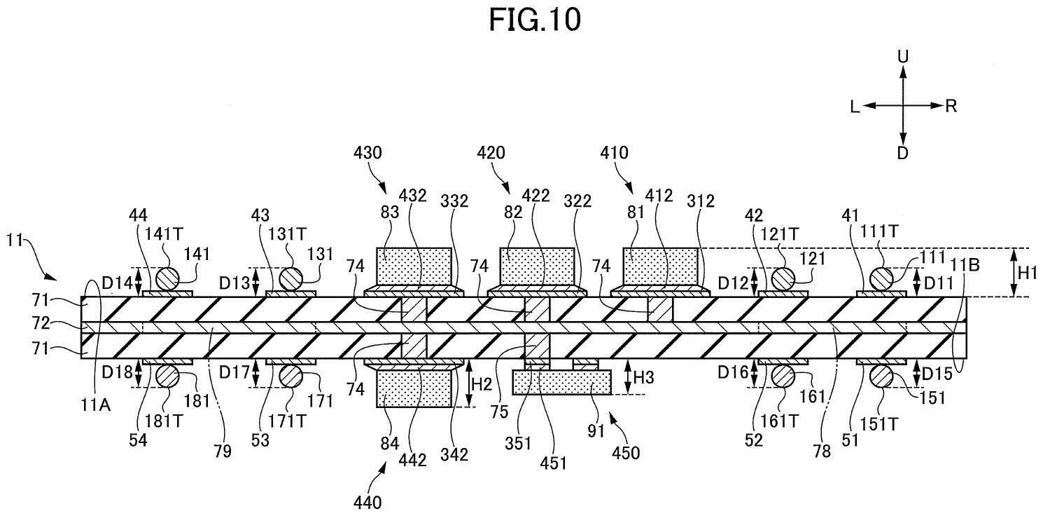

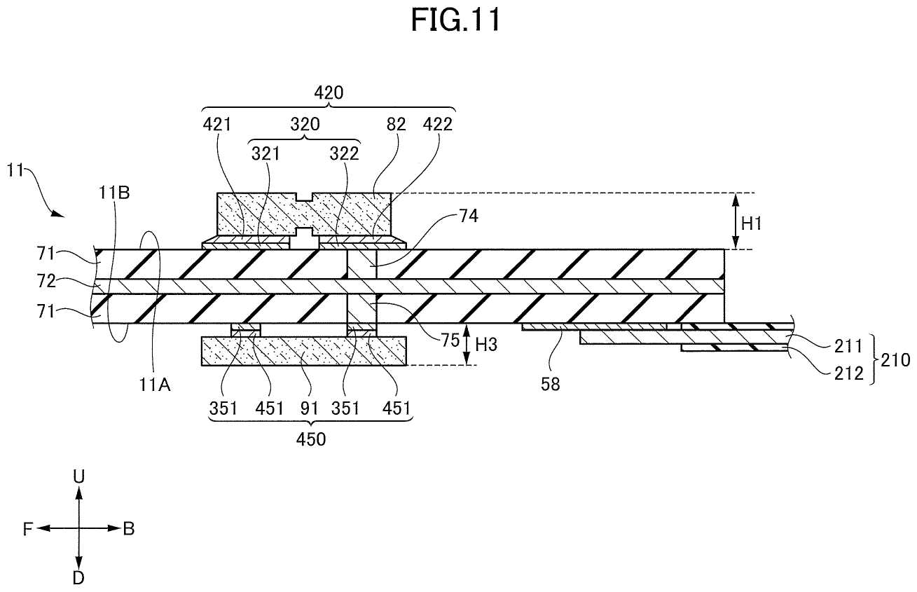

Here, the relationship between the first substrate 11 and the coaxial wires and the electric wires included in the multicore cable 2 and capacitors and an IC chip mounted on the first substrate 11 will be described. FIG. 4 is a top view illustrating the first substrate 11, coaxial wires, electric wires, and capacitors. FIG. 5 is a bottom view illustrating the first substrate 11, coaxial wires, electric wires, and capacitors, and an IC chip. FIG. 6, FIG. 7, FIG. 8, and FIG. 9 are cross-sectional views illustrating the first substrate 11, coaxial wires, and capacitors. FIG. 10 is a cross-sectional view illustrating the first substrate 11, coaxial wires, capacitors, and an IC chip. FIG. 11 is a cross-sectional view illustrating the first substrate 11, coaxial wires, capacitors, and the IC chip. FIG. 6 corresponds to a cross-sectional view taken along the VI-VI line in FIG. 4 and FIG. 5. FIG. 7 corresponds to a cross-sectional view taken along the VII-VII line in FIG. 4 and FIG. 5. FIG. 8 corresponds to a cross-sectional view taken along the VIII-VIII line in FIG. 4 and FIG. 5. FIG. 9 corresponds to a cross-sectional view taken along the IX-IX line in FIG. 4 and FIG. 5. FIG. 10 corresponds to a cross-sectional view taken along the line X-X in FIG. 4 and FIG. 5. FIG. 11 corresponds to a cross-sectional view taken along the line XI-XI in FIG. 4 and FIG. 5.

As illustrated in FIG. 4 and FIG. 5, the multicore cable 2 includes coaxial wires 110, 120, 130, 140, 150, 160, 170, and 180. The coaxial wires 110 and 120 are included in a coaxial wire pair 101. The coaxial wires 130 and 140 are included in a coaxial wire pair 102. The coaxial wires 150 and 160 are included in a coaxial wire pair 103. The coaxial wires 170 and 180 are included in a coaxial wire pair 104. A first differential signal is transmitted through the coaxial wire pair 101, a second differential signal is transmitted through the coaxial wire pair 102, a third differential signal is transmitted through the coaxial wire pair 103, and a fourth differential signal is transmitted through the coaxial wire pair 104.

As illustrated in FIG. 4 and FIG. 6, the coaxial wire 110 includes a central conductor 111, an insulating layer 112 provided on the periphery of the central conductor 111, an outer conductor 113 provided on the periphery of the insulating layer 112, and a jacket 114 that is insulating and provided on the periphery of the outer conductor 113. The central conductor 111 is connected to the pad 41 and the outer conductor 113 is connected to the pad 45. The coaxial wire 110 is an example of a fifth coaxial wire, the central conductor 111 is an example of a fifth central conductor, the insulating layer 112 is an example of a fifth insulating layer, the outer conductor 113 is an example of a fifth outer conductor, and the jacket 114 is an example of a fifth jacket.

As illustrated in FIG. 4 and FIG. 7, the coaxial wire 120 includes a central conductor 121, an insulating layer 122 provided on the periphery of the central conductor 121, an outer conductor 123 provided on the periphery of the insulating layer 122, and a jacket 124 that is insulating and provided on the periphery of the outer conductor 123. The central conductor 121 is connected to the pad 42 and the outer conductor 123 is connected to the pad 45. The coaxial wire 120 is an example of a first coaxial wire, the central conductor 121 is an example of a first central conductor, the insulating layer 122 is an example of a first insulating layer, the outer conductor 123 is an example of a first outer conductor, and the jacket 124 is an example of a first jacket.

As illustrated in FIG. 4 and FIG. 8, the coaxial wire 130 includes a central conductor 131, an insulating layer 132 provided on the periphery of the central conductor 131, an outer conductor 133 provided on the periphery of the insulating layer 132, and a jacket 134 that is insulating and provided on the periphery of the outer conductor 133. The central conductor 131 is connected to the pad 43 and the outer conductor 133 is connected to the pad 46. The coaxial wire 130 is an example of a second coaxial wire, the central conductor 131 is an example of a second central conductor, the insulating layer 132 is an example of a second insulating layer, the outer conductor 133 is an example of a second outer conductor, and the jacket 134 is an example of a second jacket.

As illustrated in FIG. 4 and FIG. 9, the coaxial wire 140 includes a central conductor 141, an insulating layer 142 provided on the periphery of the central conductor 141, an outer conductor 143 provided on the periphery of the insulating layer 142, and a jacket 144 that is insulating and provided on the periphery of the outer conductor 143. The central conductor 141 is connected to the pad 44 and the outer conductor 143 is connected to the pad 46. The coaxial wire 140 is an example of a sixth coaxial wire, the central conductor 141 is an example of a sixth central conductor, the insulating layer 142 is an example of a sixth insulating layer, the outer conductor 143 is an example of a sixth outer conductor, and the jacket 144 is an example of a sixth jacket.

As illustrated in FIG. 5 and FIG. 6, the coaxial wire 150 includes a central conductor 151, an insulating layer 152 provided on the periphery of the central conductor 151, an outer conductor 153 provided on the periphery of the insulating layer 152, and a jacket 154 that is insulating and provided on the periphery of the outer conductor 153. The central conductor 151 is connected to the pad 51 and the outer conductor 153 is connected to the pad 55. The coaxial wire 150 is an example of a seventh coaxial wire, the central conductor 151 is an example of a seventh central conductor, the insulating layer 152 is an example of a seventh insulating layer, the outer conductor 153 is an example of a seventh outer conductor, and the jacket 154 is an example of a seventh jacket.

As illustrated in FIG. 5 and FIG. 7, the coaxial wire 160 includes a central conductor 161, an insulating layer 162 provided on the periphery of the central conductor 161, an outer conductor 163 provided on the periphery of the insulating layer 162, and a jacket 164 that is insulating and provided on the periphery of the outer conductor 163. The central conductor 161 is connected to the pad 52 and the outer conductor 163 is connected to the pad 55. The coaxial wire 160 is an example of a third coaxial wire, the central conductor 161 is an example of a third central conductor, the insulating layer 162 is an example of a third insulating layer, the outer conductor 163 is an example of a third outer conductor, and the jacket 164 is an example of a third jacket.

As illustrated in FIG. 5 and FIG. 8, the coaxial wire 170 includes a central conductor 171, an insulating layer 172 provided on the periphery of the central conductor 171, an outer conductor 173 provided on the periphery of the insulating layer 172, and a jacket 174 that is insulating and provided on the periphery of the outer conductor 173. The central conductor 171 is connected to the pad 53 and the outer conductor 173 is connected to the pad 56. The coaxial wire 170 is an example of a fourth coaxial wire, the central conductor 171 is an example of a fourth central conductor, the insulating layer 172 is an example of a fourth insulating layer, the outer conductor 173 is an example of a fourth outer conductor, and the jacket 174 is an example of a fourth jacket.

As illustrated in FIG. 5 and FIG. 9, the coaxial wire 180 includes a central conductor 181, an insulating layer 182 provided on the periphery of the central conductor 181, an outer conductor 183 provided on the periphery of the insulating layer 182, and a that is insulating and jacket 184 provided on the periphery of the outer conductor 183. The central conductor 181 is connected to the pad 54 and the outer conductor 183 is connected to the pad 56. The coaxial wire 180 is an example of an eighth coaxial wire, central conductor 181 is an example of an eighth central conductor, the insulating layer 182 is an example of an eighth insulating layer, the outer conductor 183 is an example of an eighth outer conductor, and the jacket 184 is an example of an eighth jacket.

Capacitors 81, 82, 83 and 84 are mounted on the first substrate 11 as illustrated in FIG. 4, FIG. 5, FIG. 10 and FIG. 11. The capacitors 81 to 84 have a rectangular parallelepiped shape. For example, each of the capacitors 81 to 84 has a width of greater than or equal to 0.4 mm and less than or equal to 0.6 mm, a length of greater than or equal to 0.9 mm and less than or equal to 1.1 mm, and a height of greater than or equal to 0.4 mm and less than or equal to 0.6 mm. The capacitors 81 to 84 have two electrodes (not illustrated) at both ends in the length direction. The capacitors 81 to 83 are provided on the first surface 11A and the capacitor 84 is provided on the second surface 11B. One electrode of the capacitor 81 is connected to the pad 311 via a conductive bonding material 411 and the other electrode is connected to the pad 312 via a conductive bonding material 412. One electrode of the capacitor 82 is connected to the pad 321 via a conductive bonding material 421 and the other electrode is connected to the pad 322 via a conductive bonding material 422. One electrode of the capacitor 83 is connected to the pad 331 via a conductive bonding material 431 and the other electrode is connected to the pad 332 via a conductive bonding material 432. One electrode of the capacitor 84 is connected to the pad 341 via a conductive bonding material 441 and the other electrode is connected to the pad 342 via a conductive bonding material 442.

The capacitor 81, the pad 311, the pad 312, the conductive bonding material 411, and the conductive bonding material 412 are included in a ground guard 410. The capacitor 82, the pad 321, the pad 322, the conductive bonding material 421, and the conductive bonding material 422 are included in a ground guard 420. The capacitor 83, the pad 331, the pad 332, the conductive bonding material 431, and the conductive bonding material 432 are included in a ground guard 430. The capacitor 84, the pad 341, the pad 342, the conductive bonding material 441, and the conductive bonding material 442 are included in a ground guard 440. Ground guards 410, 420 and 430 are an example of a first ground guards and the ground guard 440 is an example of a second ground guards.

As illustrated in FIGS. 5, 10 and 11, an IC chip 91 is mounted on the first substrate 11. The IC chip 91 is provided on the second surface 11B. The IC chip 91 includes a plurality of electrodes (not illustrated) that are respectively connected to pads 351 conductive bonding materials 451. The IC chip 91, the plurality of pads 351, and the plurality of conductive bonding materials 451 are a included in ground guard 450. The ground guard 450 is an example of a second ground guard.

The conductive bonding materials 411, 412, 421, 422, 431, 432, 441, 442, and 451 are, for example, solder.

As illustrated in FIG. 4 and FIG. 5, the multicore cable 2 includes, for example, seven electric wires 210. The electric wires 210 each includes a conductor 211 and an insulating layer 212 provided on the periphery of the conductor 211. The conductors 211 of the respective electric wires 210 are connected to pads 47, 48, 49, 50, 57, 58, and 59.

As illustrated in FIG. 6 to FIG. 11, the first substrate 11 includes a plurality of insulating layers 71 and a ground layer 72 provided between the plurality of insulating layers 71. In the insulating layers 71, conductive vias 73, each of which connects the ground layer 72 and the pads 45, 46, 55, and 56, are provided. In the insulating layers 71, conductive vias 74, each of which connects the ground layer 72 and the pads 312, 322, 332, and 342, are provided. In the insulating layers 71, a conductive via 75 that connects the ground layer 72 and one pad 351 is provided. The pad 42 faces the pad 52 in the UD direction and the pad 43 faces the pad 53 in the UD direction. The ground layer 72 includes a first ground portion 78 between the pad 42 and the pad 52 and a second ground portion 79 between the pad 43 and the pad 53. The pad 41 may face the pad 52 in the UD direction and the pad 44 may face the pad 54 in the UD direction. For example, the first ground portion 78 is formed to extend between the pad 41 and the pad 51, and the second ground portion 79 is formed to extend between the pad 44 and the pad 54.

When viewed in the RL direction, the respective projected images of the ground guards 410, 420, and 430 overlap 50% or more of the projected image of a layered structure 202 (see FIG. 7) composed of the pad 42 and a portion of the central conductor 121 overlapping the pad 42 in the top view of the first surface 11A, and overlap 50% or more of the projected image of a layered structure 203 (see FIG. 8) composed of the pad 43 and a portion of the central conductor 131 overlapping the pad 43 in the top view of the first surface 11A. It is preferable that, when viewed in the RL direction, the respective projected images of the ground guards 410, 420, and 430 overlap 70% or more of the projected image of the layered structure 202 and the projected image of the layered structure 203. It is more preferable that, when viewed in the RL direction, the respective projected images of the ground guards 410, 420, and 430 overlap 90% or more of the projected image of the layered structure 202 and the projected image of the layered structure 203. When viewed in the RL direction, the projected image of a layered structure 201 (see FIG. 6) composed of the pad 41 and a portion of the central conductor 111 overlapping the pad 41 in the top view of the first surface 11A may overlap the projected image of the layered structure 202. When viewed in the RL direction, the projected image of a layered structure 204 (see FIG. 9) composed of the pad 44 and a portion of the central conductor 141 overlapping the pad 44 in the top view of the first surface 11A may overlap the projected image of the layered structure 203. The layered structure 202 is an example of a first layered structure and the layered structure 203 is an example of a second layered structure.

When viewed in the RL direction, the respective projected images of the ground guards 440 and 450 overlap 50% or more of the projected image of a layered structure 206 (see FIG. 7) composed of the pad 52 and a portion of the central conductor 161 overlapping the pad 52 in the bottom view of the second surface 11B, and overlap 50% or more of the projected image of a layered structure 207 (see FIG. 8) composed of the pad 53 and a portion of the central conductor 171 overlapping the pad 53 in the bottom view of the second surface 11B. It is preferable that, when viewed in the RL direction, the respective projected images of the ground guards 440 and 450 overlap 70% or more of the projected image of the layered structure 206 and the projected image of the layered structure 207. It is more preferable that, when viewed in the RL direction, the respective projected images of the ground guards 440 and 450 overlap 90% or more of the projected image of the layered structure 206 and the projected image of the layered structure 207. When viewed in the RL direction, the projected image of a layered structure 205 (see FIG. 6) composed of the pad 51 and a portion of the central conductor 151 overlapping the pad 51 in the bottom view of the second surface 11B may overlap the projected image of the layered structure 206. When viewed in the RL direction, the projected image of a layered structure 208 (see FIG. 9) composed of the pad 54 and a portion of the central conductor 181 overlapping the pad 54 in the bottom view of the second surface 11B may overlap the projected image of the layered structure 207. The layered structure 206 is an example of a third layered structure and the layered structure 207 is an example of a fourth layered structure.

Here, the crosstalk in the first connector 3 will be described. High speed differential signals, which are different from each other, are transmitted through the coaxial wire pairs 101, 102, 103 and 104. The central conductors 111 and 121 of the coaxial wire pair 101 are connected to the pads 41 and 42, respectively, and the central conductors 131 and 141 of the coaxial wire pair 102 are connected to the pads 43 and 44, respectively.

Also, the central conductors 151 and 161 of the coaxial wire pair 103 are connected to the pads 51 and 52, respectively, and the central conductors 171 and 181 of the coaxial wire pair 104 are connected to the pads 53 and 54, respectively. Between the pad 42 and the pad 43, the ground guards 410, 420 and 430 are provided, and between the pad 52 and the pad 53, the ground guards 440 and 450 are provided. The ground guards 410, 420, 430, 440 and 450 are each electrically connected to the ground layer 72. When viewed in the RL direction, the projected images of the ground guards 410, 420 and 430 overlap 50% or more of the projected image of the layered structure 202, overlap 50% or more of the projected image of the layered structure 203, and the projected images of the ground guards 440 and 450 overlap 50% or more of the projected image of the layered structure 206, and overlap 50% or more of the projected image of the layered structure 207. Therefore, even in a case in which the frequency of a signal that is transmitted through the coaxial wire pairs 101 to 104 is high, for example, even in a case in which the frequency is about 20 GHz, crosstalk between the coaxial wire pair 101 and the coaxial wire pair 102 and crosstalk between the coaxial wire pair 103 and the coaxial wire pair 104 can be suppressed.

Also, a first ground portion 78 is provided between the coaxial wire pair 101 and the coaxial wire pair 103, and a second ground portion 79 is provided between the coaxial wire pair 102 and the coaxial wire pair 104. Therefore, even in a case in which the frequency of a signal that is transmitted through the coaxial wire pairs 101 to 104 is high, for example, even in a case in which the frequency is about 20 GHz, crosstalk between the coaxial wire pair 101 and the coaxial wire pair 103 and crosstalk between the coaxial wire pair 102 and the coaxial wire pair 104 can be suppressed.

It is preferable that when viewed in the RL direction, the respective positions of the ground guards 410, 420 and 430 in the direction parallel to the first surface 11A overlap 50% or more of the position of the pad 42 in the direction parallel to the first surface 11A and overlap 50% or more of the position of the pad 43 in the direction parallel to the first surface 11A. This is for easily suppressing crosstalk between the coaxial wire pair 101 and the coaxial wire pair 102. It is more preferable that when viewed in the RL direction, the respective positions of the ground guards 410, 420 and 430 in the direction parallel to the first surface 11A overlap 70% or more of the positions of the pads 42 and the pad 43 in the direction parallel to the first surface 11A. It is further more preferable that when viewed in the RL direction, the respective positions of the ground guards 410, 420 and 430 in the direction parallel to the first surface 11A overlap 90% or more of the positions of the pads 42 and the pad 43 in the direction parallel to the first surface 11A. When viewed in the RL direction, the pad 41 may overlap the pad 42, and the pad 44 may overlap the pad 43.

It is preferable that when viewed in the RL direction, the respective positions of the ground guards 440 and 450 in the direction parallel to the second surface 11B overlap 50% or more of the position of the pad 52 in the direction parallel to the second surface 11B and overlap 50% or more of the position of the pad 54 in the direction parallel to the second surface 11B. This is for easily suppressing crosstalk between the coaxial wire pair 103 and the coaxial wire pair 104. It is more preferable that when viewed in the RL direction, the respective positions of the ground guards 440 and 450 in the direction parallel to the second surface 11B overlap 70% or more of the positions of the pad 52 and the pad 53 in the direction parallel to the second surface 11B. It is further more preferable that when viewed in the RL direction, the respective positions of the ground guards 440 and 450 in the direction parallel to the second surface 11B overlap 90% or more of the positions of the pad 52 and the pad 53 in the direction parallel to the second surface 11B. When viewed in the RL direction, the pad 51 may overlap the pad 52, and the pad 54 may overlap the pad 53.

As illustrated in FIG. 10, for example, the maximum heights H1 of the ground guards 410, 420, and 430 from the first surface 11A are equal to each other. It is preferable that the maximum heights H1 are greater than or equal to a distance D12 between a top portion 121T of the central conductor 121 on the pad 42 and the first surface 11A and greater than or equal to a distance D13 between a top portion 131T of the central conductor 131 on the pad 43 and the first surface 11A. This is for easily suppressing crosstalk between the coaxial wire pair 101 and the coaxial wire pair 102. For example, a distance D11 between a top portion 111T of the central conductor 111 on the pad 41 and the first surface 11A is equal to the distance D12, and a distance D14 between a top portion 141T of the central conductor 141 on the pad 44 and the first surface 11A is equal to the distance D13. The distances D11, D12, D13 and D14 may be equal to each other. The maximum height H1 is an example of a first maximum height. The top portion 121T is an example of a first top portion and the top portion 131T is an example of a second top portion. The distance D12 is an example of a first distance and the distance D13 is an example of a second distance.

Also, it is preferable that the maximum height H2 of the ground guard 440 from the second surface 11B and the maximum height H3 of the ground guard 450 from the second surface 11B are greater than or equal to a distance D16 between a top portion 161T of the central conductor 161 on the pad 52 and the second surface 11B and greater than or equal to a distance D17 between a top portion 171T of the central conductor 171 on the pad 53 and the second surface 11B. This is for easily suppressing crosstalk between the coaxial wire pair 103 and the coaxial wire pair 104. For example, a distance D15 between a top portion 151T of the central conductor 151 on the pad 51 and the second surface 11B is equal to the distance D16 and a distance D18 between a top portion 181T of the central conductor 181 on the pad 54 and the second surface 11B is equal to the distance D17. The distances D15, D16, D17 and D18 may be equal to each other. The maximum heights H2 and H3 are examples of a second maximum height. The top portion 161T is an example of a third top portion and the top portion 171T is an example of a fourth top portion. The distance D16 is an example of a third distance, and the distance D17 is an example of a fourth distance.

It should be noted that it is preferable that the maximum height H1 is greater than or equal to a distance D22 (see FIG. 7) between a top portion 125T of the central conductor 121 on the pad 45 and the first surface 11A, and greater than or equal to a distance D23 (see FIG. 8) between a top portion 135T of the central conductor 131 on the pad 46 and the first surface 11A.

This is for easily suppressing crosstalk between the coaxial wire pair 101 and the coaxial wire pair 102. For example, a distance D21 (see FIG. 6) between a top portion 115T of the central conductor 111 on the pad 45 and the first surface 11A is equal to the distance D22, and a distance D24 (see FIG. 9) between a top portion 145T of the central conductor 141 on the pad 46 and the first surface 11A is equal to the distance D23. The distances D21, D22, D23 and D24 may be equal to each other. The top portion 125T is an example of a fifth top portion and the top portion 135T is an example of a sixth top portion. The distance D22 is an example of a fifth distance and the distance D23 is an example of a sixth distance.

Also, it is preferable that the maximum heights H2 and H3 are greater than or equal to a distance D26 (see FIG. 7) between a top portion 165T of the central conductor 161 on the pad 55 and the second surface 11B, and greater than or equal to a distance D27 (see FIG. 8) between a top portion 175T of the central conductor 171 on the pad 56 and the second surface 11B. This is for easily suppressing crosstalk between the coaxial wire pair 103 and the coaxial wire pair 104. For example, a distance D25 (see FIG. 6) between a top portion 155T of the central conductor 151 on the pad 55 and the second surface 11B is equal to the distance D26, and a distance D28 (see FIG. 9) between a top portion 185T of the central conductor 181 on the pad 56 and the second surface 11B is equal to the distance D27. The distances D25, D26, D27, and D28 may be equal to each other. The top portion 165T is an example of a seventh top portion, and the top portion 175T is an example of an eighth top portion. The distance D26 is an example of a seventh distance and the distance D27 is an example of an eighth distance.

A distance D31 between the pad 42 and the pad 43 in the RL direction is preferably greater than or equal to 30% of a distance D32 between two points where a straight line extending in the RL direction and passing through the pads 42 and 43 intersects the edges of the first substrate 11 and is more preferably greater than or equal to 40% of the distance D32. A distance D33 between the pad 52 and the pad 53 in the RL direction is preferably greater than or equal to 30% of a distance D34 between two points where a straight line extending in the RL direction and passing through the pads 52 and 53 intersects the edges of the first substrate 11 and is more preferably greater than or equal to 40% of the distance D34. This is for ensuring the areas for the ground guards 410, 420, 430, 440 and 450. The distance D31 is an example of a ninth distance, the distance D32 is an example of a tenth distance, the distance D33 is an example of an eleventh distance, and the distance D34 is an example of a twelfth distance.

In a case in which the maximum heights H1 of the ground guards 410, 420 and 430 are too high, the ground guards 410, 420 and 430 may contact the housing of the first connector 3. Thus, it is preferable that the respective upper surfaces (U surfaces) of the ground guards 410, 420, and 430 are located below the top portions of the coaxial wires 110, 120, 130, and 140 that are the farthest from the first surface 11A. Such a surface may be located above the top portion, but in this case, the difference between the height of the top portion and the height of the surface with respect to the first surface 11A is preferably less than or equal to 0.2 mm.

In a case in which the maximum height H2 of the ground guard 440 is too high, the ground guard 440 may contact the housing of the first connector 3. Thus, it is preferable that the lower surface (D surface) of the ground guard 440 is located above the top portions of the coaxial wires 150, 160, 170, and 180 that are the farthest from the second surface 11B. Such a surface may be located below the top portion, but in this case, the difference between the height of the top portion and the height of the surface with respect to the second surface 11B is less than or equal to 0.2 mm.

It should be noted that the upper surface (U surface) of and the lower surface (D surface) of ground guards are not required to be flat. For example, in a case in which a ground guard includes a capacitor, a protrusion/recess associated with an electrode may be present on the upper surface (U surface) or the lower surface (D surface). The maximum height in such a case is the distance from the reference surface (the first surface or the second surface) to a portion that is the farthest away from the reference surface. In a case in which a central conductor is bonded to a pad by a conductive bonding material such as solder and the central conductor is covered by the conductive bonding material, the central conductor includes the conductive bonding material.

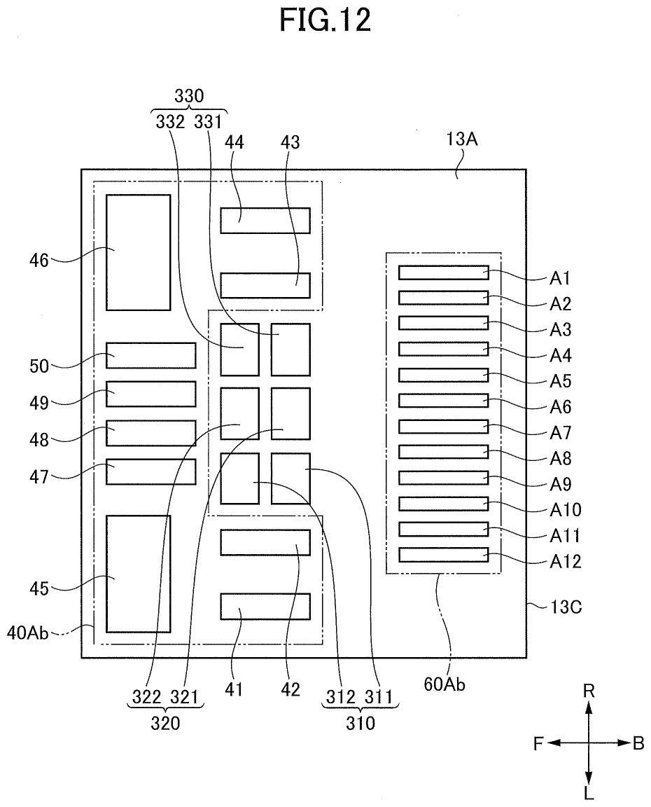

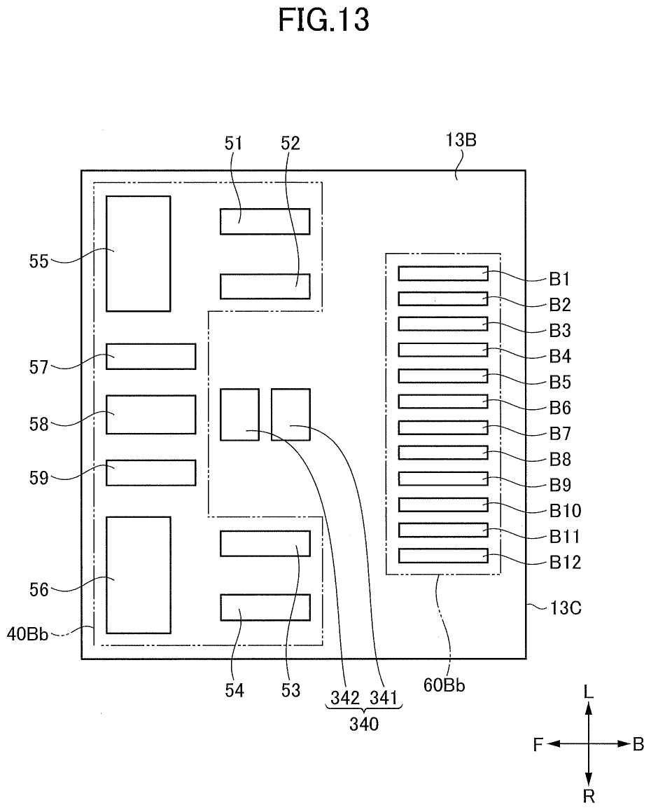

Next, pads included in the pads 40b and connector pads included in the connector pads 60b of the second substrate 13 will be described. FIG. 12 is a top view illustrating an example of pads and connector pads provided on the second substrate 13. FIG. 13 is a bottom view illustrating an example of pads and connector pads provided on the second substrate 13.

The pads 40b include first surface side pads 40Ab provided on the first surface 13A and second surface side pads 40Bb provided on the second surface 13B. As illustrated in FIG. 12, the first surface side pads 40Ab include pads 41 to 50, similarly to the first surface side pads 40Af. As illustrated in FIG. 13, the second surface side pads 40Bb include pads 51 to 59, similarly to the second surface side pads 40Bf.

As illustrated in FIG. 12, on the first surface 13A, a pad 46 is provided on the right R of a pad 45. Also, between the pad 45 and the pad 46, pads 47, 48, 49 and 50 are provided in order from the left L to the right R. On the first surface 13A, pads 41 and 42 are provided on the back B of the pad 45 and the pads 43 and 44 are provided on the back B of the pad 46. The pad 42 is provided on the right R of the pad 41 and the pad 44 is provided on the right R of the pad 43. Pad pairs 310, 320, and 330 for capacitors are provided between the pad 42 and the pad 43, from the left L to the right R in order. The pad pair 310 includes a pad 311 and a pad 312, and the pad 311 is provided on the back B of the pad 312. The pad pair 320 includes a pad 321 and a pad 322, and the pad 321 is provided on the back B of the pad 322. The pad pair 330 includes a pad 331 and a pad 332, and the pad 331 is provided on the back B of the pad 332.

As illustrated in FIG. 13, on the second surface 13B, a pad 56 is provided on the right R of a pad 55. Also, between the pad 55 and the pad 56, pads 57, 58 and 59 are provided in order from the left L to the right R. On second surface 13B, pads 51 and 52 are provided on the back B of the pad 55 and pads 53 and 54 are provided on the back B of the pad 56. A pad 52 is provided on the right R of a pad 51 and a pad 54 is provided on the right R of a pad 53. A pad pair 340 for a capacitor is provided between the pad 52 and the pad 53. The pad pair 340 includes a pad 341 and a pad 342, and the pad 341 is provided on the back B of the pad 342. Unlike the second surface 11B of the first substrate 11, pads for IC chip may not be provided.

The first surface side pads 40Ab and the second surface side pads 40Bb are connected to the end portion of the back side (B side) of the multicore cable 2.

The connector pads 60b include first surface side connector pads 60Ab provided on the first surface 13A and second surface side connector pads 60Bb provided on the second surface 13B. As illustrated in FIG. 12, the first surface side connector pads 60Ab include connector pads A1 to A12, similarly to the first surface side connector pads 60Af. The connector pads A1 to A12 of the first surface side connector pads 60Ab are arranged in a row from the right R to the left L in order on the first surface 13A. As illustrated in FIG. 13, the second surface side connector pads 60Bb include connector pads B1 to B12, similarly to the second surface side connector pads 60Bf. The connector pads B1 to B12 of the second surface side connector pads 60Bb are arranged in a row from the left L to the right R in order on the second surface 13B.

On the first surface 13A, the connector pads A1 and A12 are ground terminals (GND) for grounding. The connector pads A2 and A3 are terminals (TX1+, TX1−) for high-speed signal transmission. The connector pads A4 and A9 are terminals (VBUS) for bus power supply. The connector pad A5 is a Configuration Channel (CC) terminal. The connector pads A6 and A7 are terminals (D+, D−) for data signals. The connector pad A8 is a terminal (SBU1) for side band. The connector pads A10 and All are terminals (RX2+, RX2−) for high-speed signal reception

On the second surface 13B, the connector pads B1 and B12 are ground terminals (GND) for grounding. The connector pads B2 and B3 are terminals (TX2+, TX2−) for high-speed signal transmission. The connector pads B4 and B9 are terminals (VBUS) for bus power supply. The connector pad B5 is a terminal (VCONN) for connection power supply. The connector pad B8 is a terminal (SBU2) for side band. The connector pads B10 and B11 are terminals (RX1+, RX1−) for high-speed signal reception.

The first surface side pads 40Ab and the second surface side pads 40Bb are connected by the second circuit 14 to the first surface side connector pads 60Ab and the second surface side connector pads 60Bb of the second substrate 13. For example, the pads 41 to 44 and 51 to 54 are connected to the connector pads A2, A3, A10, A11, B2, B3, B10, and B11, which are terminals for high-speed signal transmission (TX1+, TX1−) or terminals for high-speed signal reception (RX2+, RX2−). For example, the pad 41 is connected to the connector pad A11, the pad 42 is connected to the connector pad A10, pad 43 is connected to the connector pad A3, and the pad 44 is connected to the connector pad A2. For example, the pad 51 is connected to the connector pad B2, the pad 52 is connected to the connector pad B3, the pad 53 is connected to the connector pad B10, and the pad 54 is connected to the connector pad B11.

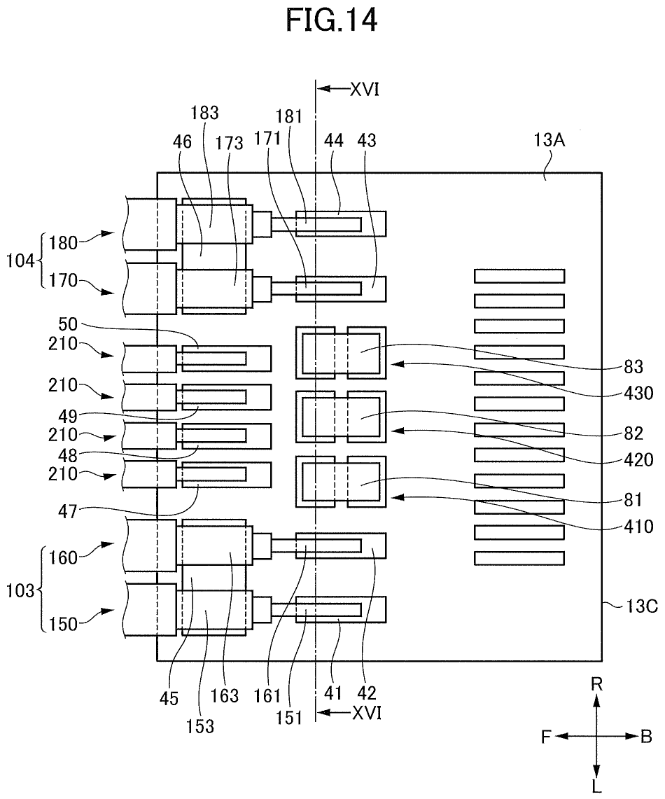

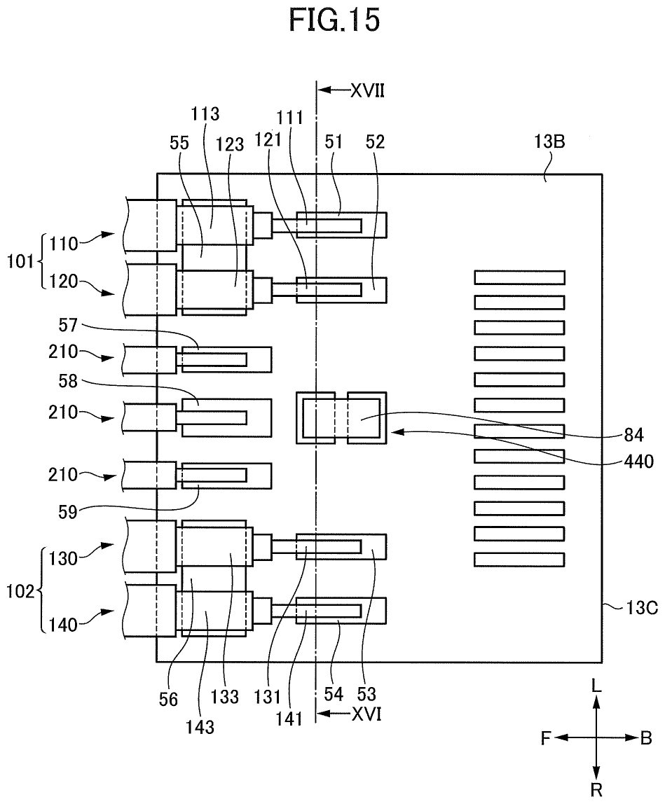

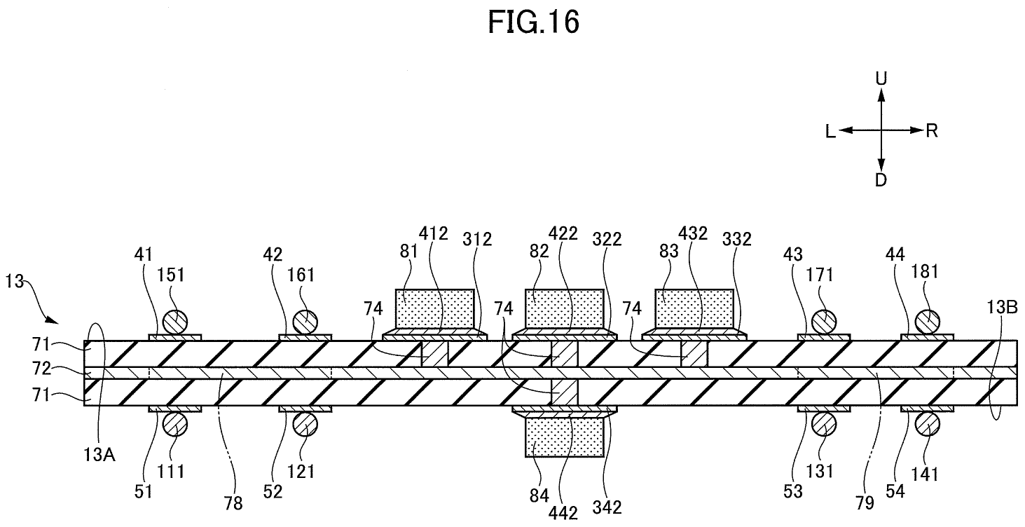

Here, the relationship between the second substrate 13 and the coaxial wires and the electric wires included in the multicore cable 2 and capacitors mounted on the second substrate 13 will be described. FIG. 14 is a top view illustrating the second substrate 13, coaxial wires, electric wires, and capacitors. FIG. 15 is a bottom view illustrating the second substrate 13, coaxial wires, electric wires, and capacitors. FIG. 16 is a cross-sectional view illustrating the second substrate 13, coaxial wires, electric wires, and capacitors. FIG. 16 corresponds to a cross-sectional view taken along the XVI-XVI line in FIG. 14 and FIG. 15.

As illustrated in FIG. 14 to FIG. 16, the central conductor 111 of the coaxial wire 110 is connected to the pad 51 and the outer conductor 113 is connected to the pad 55. The central conductor 121 of the coaxial wire 120 is connected to the pad 52 and the outer conductor 123 is connected to the pad 55. The central conductor 131 of the coaxial wire 130 is connected to the pad 53 and the outer conductor 133 is connected to the pad 56. The central conductor 141 of the coaxial wire 140 is connected to the pad 54 and the outer conductor 143 is connected to the pad 56. The central conductor 151 of the coaxial wire 150 is connected to the pad 41 and the outer conductor 153 is connected to the pad 45. The central conductor 161 of the coaxial wire 160 is connected to the pad 42 and the outer conductor 163 is connected to the pad 45. The central conductor 171 of the coaxial wire 170 is connected to the pad 43 and the outer conductor 173 is connected to the pad 46. The central conductor 181 of the coaxial wire 180 is connected to the pad 44 and the outer conductor 183 is connected to the pad 46.

Capacitors 81, 82, 83 and 84 are mounted on the second substrate 13, as illustrated in FIG. 14 to FIG. 16. Similarly to the first substrate 11, the capacitors 81 to 83 are provided on the first surface 13A and the capacitor 84 is provided on the second surface 13B.

Other configurations are similar to those of the first substrate 11.

For the second connector 4, therefore, even in a case in which the frequency of a signal that is transmitted through the coaxial wire pairs 101 to 104 is high, for example, even in a case in which the frequency is about 20 GHz, crosstalk between the coaxial wire pair 101 and the coaxial wire pair 102 and crosstalk between the coaxial wire pair 103 and the coaxial wire pair 104 can be suppressed. Also, even in a case in which the frequency of a signal that is transmitted through the coaxial wire pairs 101 to 104 is high, for example, even in a case in which the frequency is about 20 GHz, crosstalk between the coaxial wire pair 101 and the coaxial wire pair 103 and crosstalk between the coaxial wire pair 102 and the coaxial wire pair 104 can be suppressed.

For the second connector 4, an IC chip may be mounted on the second substrate 13.

The number of ground guards provided on the first surface 11A, the second surface 11B, the first surface 13A, and the second surface 13B in the present embodiment is an example. If one or more ground guards are provided on each surface, the number of ground guards is not limited.

The first and second ground guards can include electronic components, such as capacitors and an IC chips, as in the embodiment. In a case in which a capacitor or an integrated circuit chip is provided on the connector, the first and second ground guards can be configured by the capacitor or integrated circuit chip. The first and second ground guards may include another electronic component, such as a resistive element.

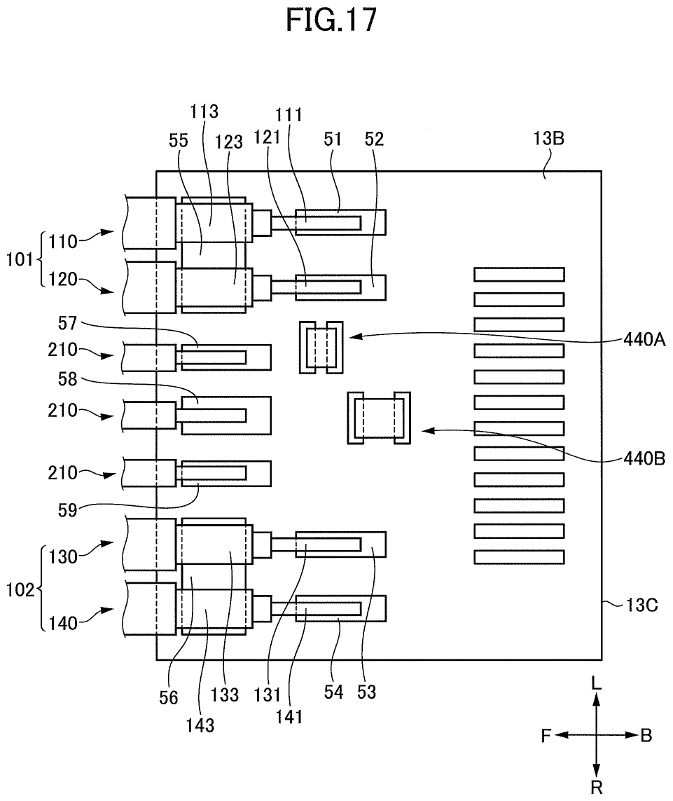

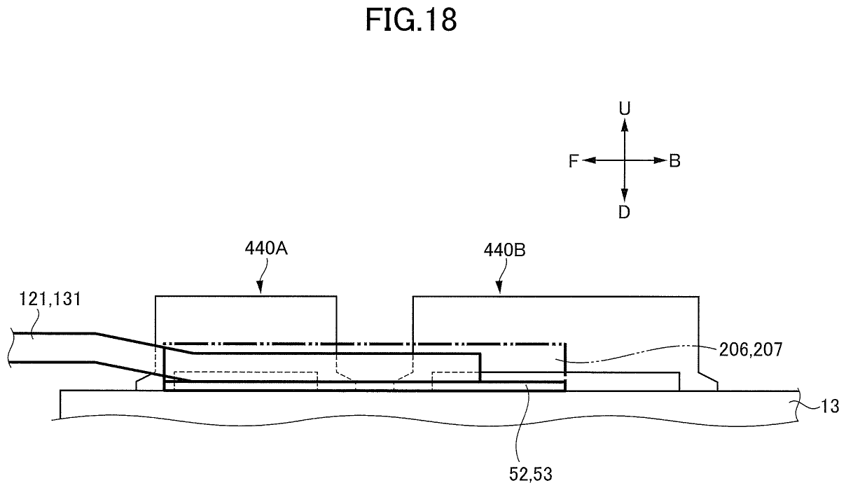

It should be noted the sizes and the positions of the first and second ground guards are not limited. FIG. 17 is a bottom view illustrating a modified example of ground guards on the second surface 13B of the second substrate 13. FIG. 18 is a schematic view illustrating the modified example of the ground guards on the second surface 13B of the second substrate 13. In this modified example, ground guards 440A and 440B are provided between the pad 52 and the pad 53 such that the positions of the ground guards 440A and 440B are displaced in the FB direction. When viewed in the RL direction, the combined projected image obtained by superimposing the projected images of the ground guards 440A and 440B overlaps 50% or more of the projected image of the layered structure 206 and also overlaps 50% or more the projected image of the layered structure 207. According to the modified example, crosstalk between the coaxial wire pair 103 and the coaxial wire pair 104 can also be suppressed. In this manner, in a case in which a plurality of ground guards are provided, even when the individual ground guards are small, crosstalk can be suppressed if the combined projected image obtained by superimposing the projected images of the plurality of ground guards overlaps 50% or more of the projected image of a target layered structure. Although not illustrated, the same applies to the ground guards 410, 420, and 430 provided on the first surface 13A of the second substrate 13. Although not illustrated, the same applies to the ground guards 410, 420, and 430 provided on the first surface 11A of the first substrate 11, and the same applies to the ground guards 440 and 450 provided on the second surface 11B of the first substrate 11.

Although the embodiment has been described in detail above, the present disclosure is not limited to a specific embodiment, and various modifications and changes can be made within the scope of claims. For example, the present disclosure can be applied not only to a multicore cable-with-connector conforming to a particular standard but also to various types of multicore cables with connectors.

### DESCRIPTION OF THE REFERENCE NUMERALS

1: multi-core cable with connector

2: multicore cable

3: first connector

4: second connector

5: connector plug

5a: metal shell

5b: pin holding plate

5c: contact pin

11: first substrate

11A, 13A: first surface

11B, 13B: second surface

12: first circuit

13: second substrate

14: second circuit

31: connector pin

40f, 40b: pads

40Af, 40Ab: first surface side pads

40Bf, 40Bb: second surface side pads

41, 42, 43, 44, 45, 46, 47, 48, 49, 50, 51, 52, 53, 54, 55, 56, 57, 58, 59: pad

60b, 60f connector pads

60Af, 60Ab: first surface side connector pads

60Bf, 60Bb: second surface side connector pads

71: insulating layer

72: ground layer

73, 74, 75: conductive via

78: first ground portion

79: second ground portion

81, 82, 83, 84: capacitor

91: Integrated circuit (IC) chip

101, 102, 103, 104: coaxial wire pair

110, 120, 130, 140, 150, 160, 170, 180: coaxial wire

111, 121, 131, 141, 151, 161, 171, 181: central conductor

111T, 115T, 121T, 125T, 131T, 135T, 141T, 145T, 151T, 155T, 161T, 165T, 171T, 175T, 181T, 185T: top portion

112, 122, 132, 142, 152, 162, 172, 182: insulating layer

113, 123, 133, 143, 153, 163, 173, 183: external conductor

114, 124, 134, 144, 154, 164, 174, 184: jacket

201, 202, 203, 204, 205, 206, 207, 208: layered structure

210: electric wire

211: conductor

212: insulating layer

310, 320, 330, 340: pad pair

311, 312, 321, 322, 331,332, 341, 342: pad

350: pads

351: pad

410, 420, 430, 440, 440A, 440B, 450: Ground guard

411, 421, 431, 441, 451: conductive bonding material

A1, A2, A3, A4, A5, A6, A7, A8, A9, A10, A11, A12, B1, B2, B3, B4, B5, B6, B7, B8, B9, B10, B11, B12: connector pad

D11, D12, D13, D14, D15, D16, D17, D18, D21, D22, D23, D24, D25, D26, D27, D28, D31, D32, D33, D34: distance

H1, H2, H3: maximum height

What is claimed is:

1. A multicore cable-with-connector comprising:
a first coaxial wire including a first central conductor;
a second coaxial wire including a second central conductor;
a third coaxial wire including a third central conductor;
a fourth coaxial wire including a fourth central conductor; and
a connector connected to one end of the first coaxial wire, one end of the second coaxial wire, one end of the third coaxial wire, and one end of the fourth coaxial wire,
wherein the connector includes a substrate having a first surface and a second surface that is an opposite side of the first surface,
wherein the substrate includes
a first pad provided on the first surface and to which the first central conductor is connected;
a second pad provided on the first surface and to which the second central conductor is connected;
a third pad provided on the second surface and to which the third central conductor is connected;
a fourth pad provided on the second surface and to which the fourth central conductor is connected; and
a ground layer provided between the first surface and the second surface,
wherein the first pad and the second pad are arranged in a particular first direction,
wherein the third pad and the fourth pad are in the first direction,
wherein the connector includes
a first ground guard provided between the first pad and the second pad on the first surface and connected to the ground layer; and
a second ground guard provided between the third pad and the fourth pad on the second surface and connected to the ground layer,
wherein when viewed in the first direction,
a projected image of the first ground guard overlaps 50% or more of a projected image of a first layered structure composed of the first pad and a portion of the first central conductor overlapping the first pad in a top view of the first surface,
the projected image of the first ground guard overlaps 50% or more of a projected image of a second layered structure composed of the second pad and a portion of the second central conductor overlapping the second pad in the top view,
a projected image of the second ground guard overlaps 50% or more of a projected image of a third layered structure composed of the third pad and a portion of the third central conductor overlapping the third pad in the top view, and
the projected image of the second ground guard overlaps 50% or more of a projected image of a fourth layered structure composed of the fourth pad and a portion of the fourth central conductor overlapping the fourth pad in the top view.

2. The multicore cable-with-connector according to claim 1,
wherein when viewed in the first direction,
a position of the first ground guard in a direction parallel to the first surface overlaps 50% or more of a position of the first pad in the direction parallel to the first surface,
the position of the first ground guard in the direction parallel to the first surface overlaps 50% or more of a position of the second pad in the direction parallel to the first surface,
a position of the second ground guard in the direction parallel to the first surface overlaps 50% or more of a position of the third pad in the direction parallel to the first surface, and
the position of the second ground guard in the direction parallel to the first surface overlaps 50% or more of a position of the fourth pad in the direction parallel to the first surface.

3. The multicore cable-with-connector according to claim 1,
wherein a first maximum height of the first ground guard from the first surface is greater than or equal to a first distance between a first top portion of the first central conductor on the first pad and the first surface,
wherein the first maximum height is greater than or equal to than a second distance between a second top portion of the second central conductor on the second pad and the first surface,
wherein a second maximum height of the second ground guard from the second surface is greater than or equal to a third distance between a third top portion of the third central conductor on the third pad and the second surface, and
wherein the second maximum height is greater than or equal to a fourth distance between a fourth top portion of the fourth central conductor on the fourth pad and the second surface.

4. The multicore cable-with-connector according to claim 3,
wherein the first coaxial wire includes
a first insulating layer provided on a periphery of the first central conductor;
a first outer conductor provided on a periphery of the first insulating layer; and
a first insulating jacket provided on a periphery of the first outer conductor,
wherein the second coaxial wire includes
a second insulating layer provided on a periphery of the second central conductor;
a second outer conductor provided on a periphery of the second insulating layer; and
a second insulating jacket provided on a periphery of the second outer conductor,
wherein the third coaxial wire includes
a third insulating layer provided on a periphery of the third central conductor;
a third outer conductor provided on a periphery of the third insulating layer; and
a third insulating jacket provided on a periphery of the third outer conductor,
wherein the fourth coaxial wire includes
a fourth insulating layer provided on a periphery of the fourth central conductor;
a fourth outer conductor provided on a periphery of the fourth insulating layer; and
a fourth insulating jacket provided on a periphery of the fourth outer conductor,
wherein the substrate includes
a first ground pad provided on the first surface and to which the first outer conductor is connected;
a second ground pad provided on the first surface and to which the second outer conductor is connected;
a third ground pad provided on the second surface and to which the third outer conductor is connected; and
a fourth ground pad provided on the second surface and to which the fourth outer conductor is connected;
wherein the first maximum height is greater than or equal to a fifth distance between a fifth top portion of the first central conductor on the first ground pad and the first surface,
wherein the first maximum height is greater than or equal to a sixth distance between a sixth top portion of the second central conductor on the second ground pad and the first surface,
wherein the second maximum height is greater than or equal to a seventh distance between a seventh top portion of the third central conductor on the third ground pad and the second surface, and
wherein the second maximum height is greater than or equal to an eighth distance between an eighth top portion of the fourth central conductor on the fourth ground pad and the second surface.

5. The multicore cable-with-connector according to claim 1,
wherein in a second direction perpendicular to the first surface, the first pad faces the third pad,
wherein in the second direction perpendicular to the first surface, the second pad faces the fourth pad,
wherein in the second direction perpendicular to the first surface, the ground layer includes
a first ground portion between the first pad and the third pad; and
a second ground portion between the second pad and the fourth pad.

6. The multicore cable-with-connector according to claim 1, further comprising:
a fifth coaxial wire including a fifth central conductor;
a sixth coaxial wire including a sixth central conductor;
a seventh coaxial wire including a seventh central conductor; and
an eighth coaxial wire including an eighth central conductor,
wherein one end of the fifth coaxial wire, one end of the sixth coaxial wire, one end of the seventh coaxial wire, and one end of the eighth coaxial wire are connected to the connector,
wherein the substrate includes
a fifth pad provided on the first surface and to which the fifth central conductor is connected;
a sixth pad provided on the first surface and to which the sixth central conductor is connected;
a seventh pad provided on the second surface and to which the seventh central conductor is connected; and
an eighth pad provided on the second surface and to which the eighth central conductor is connected,
wherein a first differential signal is transmitted to the first coaxial wire and the fifth coaxial wire,
wherein a second differential signal is transmitted to the second coaxial wire and the sixth coaxial wire,
wherein a third differential signal is transmitted to the third coaxial wire and the seventh coaxial wire,
wherein a fourth differential signal is transmitted to the fourth coaxial wire and the eighth coaxial wire,
wherein in the first direction, the first pad is provided between the first ground guard and the fifth pad,
wherein in the first direction, the second pad is provided between the first ground guard and the sixth pad,
wherein in the first direction, the third pad is provided between the second ground guard and the seventh pad, and
wherein in the first direction, the fourth pad is provided between the second ground guard and the eighth pad.

7. The multicore cable-with-connector according to claim 1,
wherein a ninth distance between the first pad and the second pad in the first direction is greater than or equal to 30% of a tenth distance between two points where a straight line extending in the first direction and passing through the first pad and the second pad intersects edges of the substrate, and
wherein an eleventh distance between the third pad and the fourth pad in the first direction is greater than or equal to 30% of a twelfth distance between two points where a straight line extending in the first direction and passing through the third pad and the fourth pad intersects edges of the substrate.

8. The multicore cable-with-connector according to claim 1, wherein the first ground guard and the second ground guard each includes a capacitor or an integrated circuit chip.

9. The multicore cable-with-connector according to claim 1,
wherein a plurality of first ground guards are provided between the first pad and the second pad on the first surface, and
wherein when viewed in the first direction, a first combined projected image obtained by superimposing projected images of the plurality of first ground guards overlaps 50% or more of the projected image of the first layered structure and overlaps 50% or more of the projected image of the second layered structure.

10. The multicore cable-with-connector according to claim 1,
wherein a plurality of second ground guards are provided between the third pad and the fourth pad on the second surface, and
wherein when viewed in the first direction, a second combined projected image obtained by superimposing projected images of the plurality of second ground guards overlaps 50% or more of the projected image of the third layered structure and overlaps 50% or more of the projected image of the fourth layered structure.

11. A multicore cable-with-connector comprising:
a first coaxial wire;
a second coaxial wire;
a third coaxial wire;
a fourth coaxial wire;
a fifth coaxial wire;
a sixth coaxial wire;
a seventh coaxial wire;
an eighth coaxial wire; and
a connector connected to one end of the first coaxial wire, one end of the second coaxial wire, one end of the third coaxial wire, one end of the fourth coaxial wire, one end of the fifth coaxial wire, one end of the sixth coaxial wire, one end of the seventh coaxial wire, and one end of the eighth coaxial wire,
wherein the first coaxial wire includes
a first central conductor;
a first insulating layer provided on a periphery of the first central conductor;
a first outer conductor provided on a periphery of the first insulating layer; and
a first insulating jacket provided on a periphery of the first outer conductor,
wherein the second coaxial wire includes
a second central conductor;
a second insulating layer provided on a periphery of the second central conductor;
a second outer conductor provided on a periphery of the second insulating layer; and
a second insulating jacket provided on a periphery of the second outer conductor,
wherein the third coaxial wire includes
a third central conductor;
a third insulating layer provided on a periphery of the third central conductor;
a third outer conductor provided on a periphery of the third insulating layer; and
a third insulating jacket provided on a periphery of the third outer conductor,
wherein the fourth coaxial wire includes
a fourth central conductor;
a fourth insulating layer provided on a periphery of the fourth central conductor;
a fourth outer conductor provided on a periphery of the fourth insulating layer; and
a fourth insulating jacket provided on a periphery of the fourth outer conductor,
wherein the fifth coaxial wire includes
a fifth central conductor;
a fifth insulating layer provided on a periphery of the fifth central conductor;
a fifth outer conductor provided on a periphery of the fifth insulating layer; and
a fifth insulating jacket provided on a periphery of the fifth outer conductor,
wherein the sixth coaxial wire includes
a sixth central conductor;
a sixth insulating layer provided on a periphery of the sixth central conductor;
a sixth outer conductor provided on a periphery of the sixth insulating layer; and
a sixth insulating jacket provided on a periphery of the sixth outer conductor,
wherein the seventh coaxial wire includes
a seventh central conductor;
a seventh insulating layer provided on a periphery of the seventh central conductor;
a seventh outer conductor provided on a periphery of the seventh insulating layer; and
a seventh insulating jacket provided on a periphery of the seventh outer conductor,
wherein the eighth coaxial wire includes
an eighth central conductor;
an eighth insulating layer provided on a periphery of the eighth central conductor;
an eighth outer conductor provided on a periphery of the eighth insulating layer; and
an eighth insulating jacket provided on a periphery of the eighth outer conductor,
wherein a first differential signal is transmitted to the first coaxial wire and the fifth coaxial wire,
wherein a second differential signal is transmitted to the second coaxial wire and the sixth coaxial wire,
wherein a third differential signal is transmitted to the third coaxial wire and the seventh coaxial wire,
wherein a fourth differential signal is transmitted to the fourth coaxial wire and the eighth coaxial wire,
wherein the connector includes a substrate having a first surface, a second surface that is an opposite side of the first surface, and a third surface that is a surface at a front end in a connector insertion direction and that connects the first surface and the second surface,
wherein the substrate includes
a first pad provided on the first surface and to which the first central conductor is connected;
a second pad provided on the first surface and to which the second central conductor is connected;
a third pad provided on the second surface and to which the third central conductor is connected;
a fourth pad provided on the second surface and to which the fourth central conductor is connected;
a fifth pad provided on the first surface and to which the fifth central conductor is connected;
a sixth pad provided on the first surface and to which the sixth central conductor is connected;
a seventh pad provided on the second surface and to which the seventh central conductor is connected;
an eighth pad provided on the second surface and to which the eighth central conductor is connected;
a first ground pad provided on the first surface and to which the first outer conductor and the fifth outer conductor are connected;
a second ground pad provided on the first surface and to which the second outer conductor and the sixth outer conductor are connected;
a third ground pad provided on the second surface and to which the third outer conductor and the seventh outer conductor are connected;
a fourth ground pad provided on the second surface and to which the fourth outer conductor and the eighth outer conductor are connected; and
a ground layer provided between the first surface and the second surface,
wherein in a top view of the first surface, the first pad and the second pad are arranged in a first direction parallel to the third surface,
wherein the third pad and the fourth pad are arranged in the first direction,
wherein in a second direction perpendicular to the first surface, the first pad faces the third pad,
wherein in the second direction perpendicular to the first surface, the second pad faces the fourth pad,
wherein the connector includes
a first ground guard including a capacitor that is provided between the first pad and the second pad on the first surface and that is connected to the ground layer; and
a second ground guard including a capacitor that is provided between the third pad and the fourth pad on the second surface and that is connected to the ground layer,
wherein in the first direction, the first pad is provided between the first ground guard and the fifth pad,
wherein in the first direction, the second pad is provided between the first ground guard and the sixth pad,
wherein in the first direction, the third pad is provided between the second ground guard and the seventh pad,
wherein in the first direction, the fourth pad is provided between the second ground guard and the eighth pad,
wherein when viewed in the first direction,
a projected image of the first ground guard overlaps 50% or more of a projected image of a first layered structure composed of the first pad and a portion of the first central conductor overlapping the first pad in the top view of the first surface,
the projected image of the first ground guard overlaps 50% or more of a projected image of a second layered structure composed of the second pad and a portion of the second central conductor overlapping the second pad in the top view,
a projected image of the second ground guard overlaps 50% or more of a projected image of a third layered structure composed of the third pad and a portion of the third central conductor overlapping the third pad in the top view, and
the projected image of the second ground guard overlaps 50% or more of a projected image of a fourth layered structure composed of the fourth pad and a portion of the fourth central conductor overlapping the fourth pad in the top view,
wherein in the second direction perpendicular to the first surface, the ground layer includes
a first ground portion between the first pad and the third pad; and
a second ground portion between the second pad and the fourth pad.
